(19) United States
(12) Patent Application Publication
(10) Pub. No.: US 2015/0318119 A1
(43) Pub. Date: Nov. 5, 2015

(54) CATION-EXCHANGED QUANTUM DOT PHOTOANODES AND SOLAR CELLS

(71) Applicants: LOS ALAMOS NATIONAL SECURITY, LLC, Los Alamos, NM (US); SHARP CORPORATION, Abeno-ku, Osaka (JP)

(72) Inventors: Hunter MCDANIEL, Los Alamos, NM (US); Nobuhiro FUKE, Osaka-shi (JP); Victor I. KLIMOV, Los Alamos, NM (US)

(21) Appl. No.: 14/648,768

(22) PCT Filed: Dec. 4, 2012
(86) PCT No.: PCT/US12/67786

§ 371 Date: Jun. 1, 2015

(51) Int. Cl. H01G 9/20; H01L 31/032; H01L 51/42; H01L 31/0352; H01L 31/18

(52) U.S. Cl. CPC H01G 9/2031; H01L 31/035218; H01L 31/186; H01L 31/18; H01L 51/426; H01L 31/0322; H01L 2031/0344

(57) ABSTRACT

Embodiments of photoanodes and quantum dot-sensitized solar cells (QDSSCs) comprising colloidal, cation-exchanged quantum dots are disclosed. The quantum dots include a core and an outer cation-exchanged layer having a cation composition that differs from a cation composition of the core. Methods of making the quantum dots, photoanodes, and QDSSCs also are disclosed.

### ACKNOWLEDGMENT OF GOVERNMENT SUPPORT

This invention was made with government support under Contract No. DE-AC52-06NA25396 awarded by the U.S. Department of Energy. The government has certain rights in the invention.

### FIELD

This disclosure concerns cation-exchanged quantum dot sensitized photoanodes and solar cells, and methods of making the same.

### PARTIES TO JOINT RESEARCH AGREEMENT

The research work described here was performed under a Cooperative Research and Development Agreement (CRADA) between Los Alamos National Laboratory (LANL) and Sharp Corporation, Japan, CRADA number LA11C10656.

### BACKGROUND

Photoelectrochemical cells (PECs) based on a mesoporous nanocrystalline TiO₂ film sensitized with organic or organometallic dyes have been studied as a potential low cost alternative to more traditional, solid-state photovoltaics, such as solar cells based on Cu(In,Ga)Se₂ (CIGS), which currently hold the power conversion efficiency record among thin-film technologies at >20%.

As part of search for new approaches to improve efficiency over past several years, a number of research groups reported studies of PECs in which the sensitizing dyes are substituted with semiconductor nanocrystalline quantum dots (NQDs) of materials such as InP, CdS, CdSe, CdTe, PbS and InAs. It has been demonstrated that semiconductor NQDs can function as efficient sensitizers across a broad spectral range from the visible to mid-infrared, and offer advantages such as increased band gap tunability, long exciton lifetimes, and low-cost solution processability. However, a major factor limiting the performance of quantum dot solar cells is high recombination at the surface, which results in open-circuit voltages far smaller than the absorber band gap and reduced photocurrent. Achieving desirable performance requires high temperature sintering to improve carrier collection and also to capture near-IR photons. However, sintering increases cost and typically results in loss of quantum confinement (i.e. they are no longer quantum dot solar cells).

### SUMMARY

Embodiments of photoanodes and quantum dot-sensitized solar cells (QDSSCs) comprising colloidal, cation-exchanged quantum dots (ceQDs) are disclosed. The quantum dots include a core and an outer cation-exchanged layer having a cation composition that differs from a cation composition of the core. Methods of making the ceQDs, photoanodes, and QDSSCs also are disclosed.

A photoanode includes an electrically conducting substrate, a porous metal oxide film on the electrically conducting substrate, and a plurality of colloidal, cation-exchanged quantum dots on the metal oxide film, wherein the QDs have a core, an outer cation-exchanged layer with a cation composition that differs from a cation composition of the core, and a plurality of capping ligands having a formula RNH₂ where R is C2-C6 alkyl, such as t-butylamine.

The ceQD core may be a semiconductor and/or a I-II-IV-VI semiconductor. Alternatively, the ceQD core may be PbSe or PbSeₓS₁₋ₓ wherein 0≦x<1. In some embodiments, the core is CuInSeₓS₂₋ₓ or CuZn_{0.5}Sn_{0.5}SeₓS₂₋ₓ, where 0<x<2, such as 1.3≦x≦1.7. In Some embodiments, the ceQDs have a band gap ranging from 1.0-3.0 eV, such as from 1.0 to 2.0 eV.

The outer cation-exchanged layer includes M cations wherein M is Cd, Zn, Sn, Ag, Au, Hg, Cu, In, or a combination thereof. In some embodiments, M is Cd or Zn. The ceQDs may have a cation concentration comprising 0.1-40% M. In certain embodiments, M is Cd or Zn and the quantum dot cation concentration comprises 1-20% M. The ceQD may have substantially the same diameter before and after undergoing cation exchange to form the outer cation-exchanged layer.

The metal oxide film comprises a transition metal, and may have a thickness of 1 to 30 μm. In some embodiments, the metal oxide is TiO₂, SnO₂, ZrO₂, ZnO, WO₃, Nb₂O₅, Ta₂O₅, BaTiO₂, SrTiO₃, ZnTiO₃, CuTiO₃, or a combination thereof. In some embodiments, the metal oxide film is TiO₂. The metal oxide film may include a first, light-absorbing layer comprising mesoporous metal oxide particles having a diameter of 1 to50 nm, such as a diameter of 10 to50 nm, and a second, light-scattering layer comprising metal oxide particles having a diameter of 100 to 500 nm, such as a diameter of 300 to 500 nm. The first layer may have has a thickness of 1 to 30 μm and the second layer may have a thickness of 1 to 10 μm.

A QDSSC includes a photoanode, a counter electrode, and an electrolyte in contact with both the photoanode and the counter electrode. In some examples, the electrically conducting substrate is fluorinated tin oxide on glass. The counter electrode may be Cu_{y}S (0.5<y<2) on fluorinated tin oxide-coated glass. In certain embodiments, the electrolyte is a polysulfide electrolyte. The polysulfide electrolyte may be a solution comprising a solvent selected from water, a lower alkyl alcohol (e.g., alcohol), or a combination thereof.

Some embodiments of the QDSSCs produce a current density that remains the same or increases over a time period, such as greater than 24 hours, or greater than 72 hours, when exposed to simulated AM1.5 sunlight or in the dark. In some embodiments, the QDSSC has a current density ≧5 mA/cm² over a voltage range from 0 V to 0.6 V. The QDSSC may have an AM1.5 power conversion efficiency (PCE) greater than 2%, such as ≧5%.

Also disclosed are methods of making QDSSCs including a photoanode, comprising (i) synthesizing colloidal quantum dots, (ii) exposing the colloidal quantum dots to a cation solution under conditions effective to produce cation exchange in an outer layer of the colloidal quantum dots thereby forming colloidal, cation-exchanged quantum dots having a core and an outer cation-exchanged layer, (iii) capping the colloidal, cation-exchanged quantum dots with a C2-C6 primary amine (e.g., t-butylamine) to form colloidal capped cation-exchanged quantum dots, (iv) providing a porous metal oxide film on an electrically conducting substrate, and (v) exposing the porous metal oxide film to the colloidal capped cation-exchanged quantum dots for an effective period of time to produce a quantum-dot sensitized metal oxide film suitable for use as a photoanode.

In some embodiments, colloidal quantum dots are synthesized by combining copper, indium, selenium, and sulfide precursors to form nucleated CuInSeₓS₂₋ₓ, heating the nucleated CuInSeₓS₂₋ₓ to a temperature from 220° C. to 240° C. and allowing the reaction to proceed for an effective period of time to produce CuInSeₓS₂₋ₓ quantum dots wherein 0≦x<2.

Cation exchange may be performed by dispersing the colloidal quantum dots in a solvent to produce a quantum dot suspension, combining the quantum dot suspension with the cation solution, wherein the cation solution comprises Cd, Zn, Sn, Ag, Au, Hg, Cu, and/or In cations, heating the combined quantum dot suspension and cation solution to a temperature from 20-150° C., and maintaining the temperature for a time of 1-60 minutes, such as for 5-15 minutes. In some embodiments, the temperature and time are selected to produce partial cation exchange in the outer layer.

Cation-exchanged quantum dots may be attached to the porous (e.g., mesoporous) metal oxide film by exposing the porous metal oxide film on the electrically conducting substrate to a suspension comprising the colloidal capped, cation-exchanged quantum dots for 12-48 hours.

The foregoing and other objects, features, and advantages of the invention will become more apparent from the following detailed description, which proceeds with reference to the accompanying figures.

### BRIEF DESCRIPTION OF THE DRAWINGS

FIG. 1 is a schematic diagram of an exemplary quantum dot sensitized solar cell.

FIG. 2 is a graph of current density versus voltage for quantum-dot sensitized solar cells (QDSSCs) including CuInS₂ quantum dots (QDs) and cadmium-exchanged CuInS₂ QDs; the cation exchange was performed at 125° C.

FIG. 3 is a graph of external quantum efficiency versus photon energy for the QDSSCs of FIG. 2.

FIG. 4 is a graph of absorbance versus photon energy for QDs synthesized with increasing amounts of TOP-Se.

FIG. 5 is two high-resolution transmission electron microscopy TEM images of CuInSe_{1.4}S_{0.6} QDs.

FIG. 6 is a series of high (top) and lower (bottom) magnification TEM images of CuInSe_{1.4}S_{0.6} QDs after Cd-oleate treatment at 50° C.

FIG. 7 is a graph illustrating the relative fractions of Cu, In, and Cd cations in CuInSeₓS₂₋ₓ QDs after exposure to Cd-oleate. Measurements were obtained by inductively coupled plasma atomic emission spectroscopy.

FIG. 8 is a graph of absorbance and normalized phospholuminescence versus photon energy for CuInSe_{1.4}S_{0.6} QDs before and after exposure to Cd-oleate at the indicated temperatures. The QDs were subsequently recapped with short-chain amines.

FIG. 9 is a graph illustrating the normalized phospholuminescence decay of the QDs of FIG. 8.

FIG. 10 is a graph of absorbance and normalized phospholuminescence versus photon energy for CuInSe_{1.4}S_{0.6} QDs before and after exposure to Zn-oleate at the indicated temperatures. The QDs were subsequently recapped with t-butylamine.

FIG. 11 is a graph illustrating the normalized phospholuminescence decay of the QDs of FIG. 8 after attachment to mesoporous TiO₂.

FIG. 12 is an SEM cross-section image of a QD-sensitized mp-TiO₂ film on FTO-coated glass, magnification 9827×, WD 11.4 mm, HV 10.0 kV, Spot 3.0, Tilt 0.0, scale bar 5.0 μm.

FIG. 13 is a raw EDX line scan of the cross-section of FIG. 12 showing the uniform concentration of QDs throughout the mp-TiO₂ film.

FIG. 14 is a graph of current density versus voltage under simulated AM1.5 sunlight for QDSSCs fabricated with the cation-exchanged quantum dots of FIGS. 8-9. Measurements were obtained one day after fabrication. These QDSSCs used a polysulfide electrolyte with a solvent composed of 100% water.

FIG. 15 shows the external quantum efficiency (EQE) spectra (EQE vs. photon energy) for the QDSSCs of FIG. 14.

FIG. 16 shows 1-T (T=transmittance) spectra (1-T vs. photon energy) for cation-exchanged QD-sensitized mesoporous TiO₂ films. Scattering from the mp-TiO₂ was subtracted from the spectra.

FIG. 17 is a graph of current density versus voltage for QDSSCs including the quantum dots of FIG. 10. These QDSSCs used a polysulfide electrolyte with a solvent composed of 50% methanol, 50% water.

FIG. 18 is a graph of current density versus voltage for QDSSCs including the CuInSe_{1.4}S_{0.6} QDs that were cation-exchanged with Cd. These QDSSCs used a polysulfide electrolyte with a solvent composed of 50% methanol, 50% water.

FIG. 19 is a graph of current density versus voltage under simulated AM1.5 sunlight for a QDSSC fabricated with QDs treated with Cd-oleate at 50° C., and incorporating a scattering layer of TiO₂. J_{sc}=10.5 mA/cm², V_{oc}=0.55 V, FF=0.604, PCE=3.45%. This QDSSC used a polysulfide electrolyte with a solvent composed of 100% water.

FIG. 20 is a graph of current density versus voltage under simulated AM1.5 sunlight for the QDSSCs of FIG. 14. Measurements were obtained four days after fabrication.

FIG. 21 shows 1-T spectra for Cd-exchanged QD-sensitized mesoporous TiO₂ films. LE—ligand exchange; cation exchange performed at 125° C. The number following “LE” refers to the number of hours the QDs were exposed to t-butylamine. “NoLE”=no ligand exchange.

FIG. 22 shows 1-T spectra for Cd-exchanged QD-sensitized mesoporous TiO₂ films. LE—ligand exchange; cation exchange performed at 50° C. The number following “LE” refers to the number of hours the QDs were exposed to t-butylamine. “NoLE”=no ligand exchange.

FIG. 23 is a graph of current density versus voltage for QDSSCs in which the polysulfide electrolyte included 0-75% methanol. The cation exchange was performed at 50° C. on CuInSe_{1.4}S_{0.6} quantum dots, and the cation-exchanged QDs then were capped with t-butylamine using the “0 hr” exposure.

FIG. 24 is a graph of current versus voltage for a QDSSC including Cd-exchanged CuInSe_{1.4}S_{0.6} QDs capped with t-butylamine and a polysulfide electrolyte including 75% methanol/25% H₂O. The data was obtained under the following conditions: temperature—30±5.0° C.; device area—0.2223 cm²; irradiance—1000.0 W/m²; spectrum: ASTM G173 global. J_{sc}=17.565 mA/cm², V_{oc}=0.5402 V, FF=0.5410, PCE=5.13%.

FIG. 25 is a graph of quantum efficiency versus wavelength for the QDSSC of FIG. 23. The data was obtained under the following conditions: temperature—25.0±2° C.; device area—0.2200 cm²; zero voltage bias; light bias=1.00 mA into 0.22 cm².

### DETAILED DESCRIPTION

Embodiments of photoanodes and quantum dot-sensitized solar cells (QDSSCs) comprising cation-exchanged quantum dots (ceQDs) are disclosed. The disclosed photoanodes and QDSSCs include colloidal, cation-exchanged quantum dots in which surface cations of the ceQDs have been partially exchanged to passivate surface charge traps that serve as recombination centers, thereby enhancing chemical stability, increasing photocurrent, and increasing photovoltage. Methods of making photoanodes and QDSSCs comprising the ceQDs are also disclosed.

### I. DEFINITIONS AND ABBREVIATIONS

The following explanations of terms and abbreviations are provided to better describe the present disclosure and to guide those of ordinary skill in the art in the practice of the present disclosure. As used herein, “comprising” means “including” and the singular forms “a” or “an” or “the” include plural references unless the context clearly dictates otherwise. The term “or” refers to a single element of stated alternative elements or a combination of two or more elements, unless the context clearly indicates otherwise.

Unless explained otherwise, all technical and scientific terms used herein have the same meaning as commonly understood to one of ordinary skill in the art to which this disclosure belongs. Although methods and materials similar or equivalent to those described herein can be used in the practice or testing of the present disclosure, suitable methods and materials are described below. The materials, methods, and examples are illustrative only and not intended to be limiting. Other features of the disclosure are apparent from the following detailed description and the claims.

Unless otherwise indicated, all numbers expressing quantities of components, percentages, temperatures, times, and so forth, as used in the specification or claims are to be understood as being modified by the term “about.” Unless otherwise indicated, non-numerical properties such as colloidal, continuous, crystalline, and so forth as used in the specification or claims are to be understood as being modified by the term “substantially,” meaning to a great extent or degree. Accordingly, unless otherwise indicated, implicitly or explicitly, the numerical parameters and/or non-numerical properties set forth are approximations that may depend on the desired properties sought, limits of detection under standard test conditions/methods, limitations of the processing method, and/or the nature of the parameter or property. When directly and explicitly distinguishing embodiments from discussed prior art, the embodiment numbers are not approximates unless the word “about” is recited.

A. Abbreviations

AM air mass coefficient

ceQD colloidal, cation-exchanged quantum dot

EQE external quantum efficiency

FF fill factor

FTO fluorinated tin oxide

IPCE incident photon to charge carrier efficiency (equivalent to EQE)

J_{SC} short circuit current density

PCE power conversion efficiency

PL phospholuminescence

QD quantum dot

QDSSC quantum dot sensitized solar cell

QE quantum efficiency

QY quantum yield

SSC sensitized solar cell

tBA t-butylamine

TOP-Se trioctylphosphine selenide

V_{oc} open-circuit voltage

B. Definitions

In order to facilitate review of the various embodiments of the disclosure, the following explanations of specific terms are provided:

Air Mass Coefficient (AM): The air mass coefficient defines the direct optical path length through the Earth's atmosphere as a ratio relative to the path length vertically upwards. AM is often used to characterize the solar spectrum after solar radiation has traveled through the atmosphere. It is also used to characterize solar cell performance under standardized conditions. AM1.5 represents a path length of 1.5× atmosphere thickness, and is commonly used to represent the spectrum at mid-latitudes.

Colloidal: A term referring to particles having a sufficiently small size to remain dispersed in a liquid suspension without a significant amount of settling. Colloidal particles typically have a diameter between 1-100 nm.

Current density: A term referring to the amount of current per unit area. Current density is typically expressed in units of mA/cm².

Efficiency or power conversion efficiency: As used herein with respect to solar cells, the term “efficiency” by itself refers power conversion efficiency, i.e., the ratio of electrical output of a solar cell to the incident energy. Typically efficiency is reported as a percentage of solar energy that is converted to electrical energy. The cell's power output (watts) at its maximum power point is divided by the input light (W/m²) and the surface area of the solar cell (m²).

External quantum efficiency: A ratio of the number of charge carriers collected by a solar cell to the number of incident photons of a given energy striking the solar cell. EQE=(electrons per second)÷(photons per second). A related term is “internal quantum efficiency” or IQE, which is a ratio of the number of charge carriers collected by the solar cell to the number of incident photons of a given energy that are absorbed by the solar cell.

Fill factor: The ratio of maximum obtainable power to the product of the open-circuit voltage and short-circuit current for a solar cell.

Hole: An electron hole is the conceptual and mathematical opposite of an electron. The term “hole” describes the lack of electron at a position where an electron could exist in an atom or an atomic lattice. In a semiconductor, a hole in a valence band is generated when an electron moves from the valence band to the conduction band. Hole conduction occurs when a hole “moves” through the valence band, i.e., when another electron in the valence band moves to fill the hole, thereby generating a new hole.

Monolayer: A single layer of atoms. As used herein, an “outer monolayer” refers to a one-atom thick layer of surface cations and anions surrounding a quantum dot core.

Pore: One of many openings or void spaces in a solid substance. Pores are characterized by their diameters. According to IUPAC notation, mesopores are mid-sized pores with diameters from 2 nm to 50 nm. Porosity is a measure of the void spaces or openings in a material, and is measured as a fraction, between 0-1, or as a percentage between 0-100%.

Quantum dot (QD): A nanoscale particle that exhibits size-dependent electronic and optical properties due to quantum confinement. The QDs disclosed herein generally have at least one dimension less than about 100 nanometers. The disclosed QDs may be colloidal QDs, i.e., QDs that may remain in suspension when dispersed in a liquid medium. Some QDs are made from a binary semiconductor material having a formula MX, where M is a metal and X typically is selected from sulfur, selenium, tellurium, nitrogen, phosphorus, arsenic, antimony or mixtures thereof. Exemplary binary QDs include CdS, CdSe, CdTe, GaAs, InAs, InN, InP, InSb, PbS, PbSe, PbTe, ZnS, ZnSe, and ZnTe. Other QDs are tertiary or ternary alloy QDs including, but not limited to, ZnSSe, ZnSeTe, ZnSTe, CdSSe, CdSeTe, ScSTe, HgSSe, HgSeTe, HgSTe, ZnCdS, ZnCdSe, ZnCdTe, ZnHgS, ZnHgSe, ZnHgTe, CdHgS, CdHgSe, CdHgTe, ZnCdSSe, ZnHgSSe, ZnCdSeTe, ZnHgSeTe, CdHgSSe, CdHgSeTe, InGaAs, GaAlAs, InGaN, CuInS₂, CuInGaSe₂, CuZnSnSe₂, CuIn(Se,S)₂, CuZn(Se,S)₂, and CuSn(Se,S)₂ QDs. Embodiments of the disclosed QDs may be of a single material, or may comprise an inner core and an outer shell, e.g., a thin outer shell/layer formed by cation exchange. The QDs may further include a plurality of ligands bound to the quantum dot surface.

Suspension: A heterogeneous mixture in which very small particles are dispersed substantially uniformly in a liquid or gaseous medium. A liquid suspension in which the dispersed particles have a diameter between about 1-100 nm is considered to be a colloidal suspension. The particles in a colloidal suspension tend to remain in suspension instead of settling when left undisturbed.

### II. CATION-EXCHANGED QUANTUM DOT SOLAR CELLS

One strategy to capitalize on attractive absorber qualities while avoiding the problems of relying on inter-quantum dot charge transport is to use a device architecture where two non-absorbing charge transport materials sandwich a thin quantum dot absorber layer. Such a structure is found in dye-sensitized (i.e. Grätzel) solar cells, or in quantum dot-sensitized solar cells (QDSSCs). QDSSCs avoid inter-quantum dot charge transport via rapid extraction of photo-excited electrons from quantum dots to mesoporous (mp) metal oxide (e.g., TiO₂) and extraction of holes to an electrolyte.

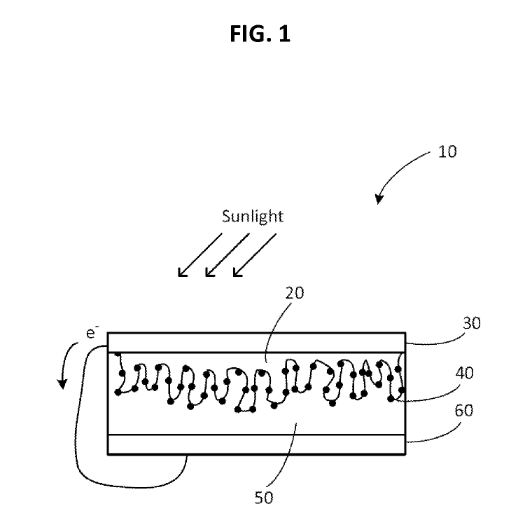

An exemplary QDSSC is shown in FIG. 1. The solar cell 10 includes a porous metal oxide film 20 on a conductive substrate 30 (e.g., fluorinated tin oxide-coated glass). Quantum dots 40 are attached to the surface of metal oxide film 20. Solar cell 10 further includes a hole-extracting and hole-transporting material 50 and a counter electrode 60.

A nanostructured, wide band gap semiconductor film, such as a mesoporous metal oxide, provides a surface area that is orders of magnitude greater than its geometric area. The surface is sensitized with a thin absorber layer comprising QDs. When incident light strikes the solar cell, the light path passes through tens to hundreds of QDs as it travels through the sensitized semiconductor film. The electrolyte, typically a redox electrolyte, fills the space around the nanostructures. The QDs absorb light and emit electrons from their excited levels into the conduction band of the mesoporous film. Oxidized QDs are reduced by the electrolyte.

A. Cation-Exchanged Quantum Dots

Embodiments of the disclosed quantum dots are colloidal, cation-exchanged quantum dots (ceQDs) comprising a core and an outer cation-exchanged layer having a cation composition that differs from a cation composition of the core. In some embodiments, the core comprises a semiconductor, a II-VI semiconductor, a I-II-IV-VI semiconductor, PbSe, or PbSeₓS₁₋ₓ where 0≦x≦1. The disclosed ceQDs typically have an average diameter from 1-20 nm, such as from 2-10 nm.

In certain embodiments, the core comprises CuInSeₓS₂₋ₓ or CuZn_{0.5}Sn_{0.5}SeₓS₂₋ₓ, where 0≦x<2, such as 1≦x<2, or 1.3≦x≦1.7. Advantageously, the quantum dot cores are nontoxic to humans and are composed of relatively earth abundant constituents.

CuInS₂ QDs have been used to make QDSSCs, but achieving desirable performance requires high temperature sintering, which can result in loss of quantum confinement and can produce a CuInS₂ film in place of individual QDs. The CuInS₂ quantum dot band gap is somewhat large, but can be minimized by increasing quantum dot size. Nonetheless, CuInS₂ QDs are limited to a minimum band gap of >1.51 eV (i.e., the band gap of the bulk material). Furthermore, increasing the quantum dot size to minimize the band gap reduces quantum dot infiltration into the mesoporous TiO₂ film, which can reduce the solar cell photocurrent and efficiency.

To overcome this disadvantage, embodiments of the disclosed QDs are alloyed with selenium to reduce the band gap and increase infrared absorption. The QDs are also surface passivated by cation exchange to limit recombination losses. Embodiments of the disclosed ceQDs have several advantages compared to CuInS₂ QDs and other QDs currently used for quantum dot-sensitized solar cells. For example, embodiments of the disclosed ceQDs have a low-cost and high-yield synthesis, a narrower band gap (up to 0.5 eV narrower) than CuInS₂ QDs of the same diameter, reduced surface trapping (indicated by increased phospholuminescence quantum yield (PL QY) and increased excited state lifetime), better material stability, dramatically enhanced QDSSC performance, and combinations thereof.

Alloying CuInS₂ QDs with selenium produces QDs having the general formula CuInSeₓS₂₋ₓ. Inclusion of selenide reduces the band gap for a given quantum dot size compared to CuInS₂ QDs. CuInSeₓS₂₋ₓ has tunable bulk band gaps ranging from 1.0-1.5 eV, with the band gap decreasing as the concentration of selenium increases. The band gap decrease is evident as the quantum dot absorption spectrum shifts significantly to the red compared to the absorption spectrum of CuInS₂ QDs synthesized with the same growth time. CuInSeₓS₂₋ₓ QDs also exhibit a large absorption coefficient and favorable transport properties. However, selenide alone (i.e., CuInSe₂) produces a less stable quantum dot and a reduced absorption-normalized phospholuminescence (PL). Thus, in certain embodiments, 1.3≦x≦1.7. In some examples, 70% of the anions in the QDs are selenium and the QDs have the composition CuInSe_{1.4}S_{0.6}.

Forming a wide band gap inorganic shell having a type I heterojunction with an emissive quantum dot core passivates the quantum dot surface and enhances PL. A thin shell (e.g., an outer cation-exchanged layer) can be effectively produced by cation exchange, in which at least some of the outer Cu and/or In cations are replaced. In one embodiment, partial cation exchange of surface cations occurs, i.e., only a portion of the surface Cu and/or In cations are replaced. In another embodiment, substantially complete or complete cation exchange of surface cations occurs, thereby forming a substantially continuous or complete outer cation-exchanged layer. In another embodiment, only surface cations are replaced, thereby forming a partial, continuous, or substantially continuous cation-exchanged outer monolayer (i.e., a one-atom thick layer of surface cations and anions surrounding the QD core). In still another embodiment, cation exchange may penetrate deeper than the QD surface, and cations on, adjacent, and/or near the QD surface may be partially or completely exchanged. In some embodiments, cation exchange is selective, and Cu or In cations may be preferentially replaced. The extent of cation exchange may be controlled by varying the temperature and/or time of the cation exchange process, and/or by varying the concentration of the cation exchange solution relative to the concentration of quantum dots exposed to the cation exchange solution.

Suitable metal cations, M, for exchange include, but are not limited to Cd, Zn, Sn, Ag, Au, Hg, Cu, In, and combinations thereof. In the case of cation exchange with Cu or In, a surface having substantially only copper or only indium cations, respectively, may result. In some embodiments, cation exchange does not change the quantum dot shape or size, in contrast to a shell that is deposited onto a quantum dot core. Thus, embodiments of the disclosed ceQDs have the same diameter before and after cation exchange is performed. As used herein, “same diameter” means that the average diameter after cation exchange may differ from the average diameter before cation exchange by less than 10%, less than 5%, less than 2%, or even less than 1%.

In one embodiment, all or substantially all of the ceQD's surface cations are replaced with M, forming an outer layer comprising (M) (Se,S), i.e., a continuous or substantially continuous outer cation-exchanged layer or outer cation-exchanged monolayer comprising (M) (Se,S). In another embodiment, only a portion of the ceQD's surface cations are exchanged. Thus, if the ceQD core comprises CuInSeₓS₂₋ₓ, partial cation exchange produces an outer cation-exchanged layer (or monolayer) comprising (Cu,M) (Se,S), (In,M) (Se,S), or (Cu,In,M) (Se,S). In certain embodiments, M is Cd and/or Zn. Each discrete ceQD has an outer cation-exchanged layer, or monolayer, surrounding its core. This outer cation-exchanged layer, or monolayer, stands in contrast to other methods, which use a selective ion layer reaction (SILAR) technique to deposit a conformal layer/thin film of, for example, CdS or ZnS over a plurality of QDs immobilized on a metal oxide film.

In certain embodiments, up to 50% of the quantum dot's Cu and/or In cations are replaced with M, such as 0.1-40%, 1-40%, 1-30%, 1-25%, 1-20%, or 1-10%. In some embodiments, Cu and In are replaced in substantially equal amounts. In other embodiments, either Cu or In is selectively replaced. Replacement selectivity may be controlled, at least in part, by controlling the temperature at which cation exchange is performed and/or by controlling the time duration of the cation exchange process. As discussed infra, in some examples indium cations were selectively replaced at lower temperatures, while Cu and In cations were both replaced to a similar extent at higher temperatures.

In some embodiments, following cation exchange with an exchange cation other than Cu or In, the cations present in a CuInSeₓS₂₋ₓ ceQD comprise 25-50% Cu, 25-50% In, and up to 50% of the exchange cation. In certain embodiments, the exchange cation is Cd and/or Zn, and the cations present in the ceQD after exchange comprise 25-50% Cu, 25-50% In, and up to 50% Cd and/or Zn, such as 35-50% Cu, 25-45% In, and 5-40% Cd and/or Zn. In some examples, the cation composition after exchange comprises 40-50% Cu, 35-45% In, and 5-25% Cd and/or Zn. In one example, partial cation exchange with Cd at 50° C. produced ceQDs having a cation composition comprising 7% Cd cations. In another example, partial cation exchange was conducted with Cd at 125° C. to produce ceQDs having a cation composition comprising 18% Cd cations.

Embodiments of the disclosed ceQDs may have a band gap ranging from 1.0 eV to 3.0 eV. In some embodiments, the band gap ranges from 1.0 eV to 2.0 eV.

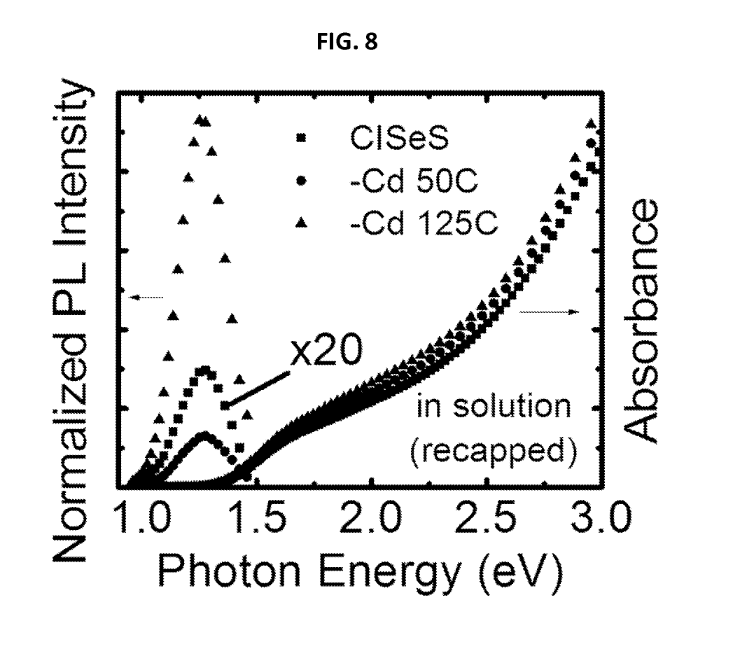

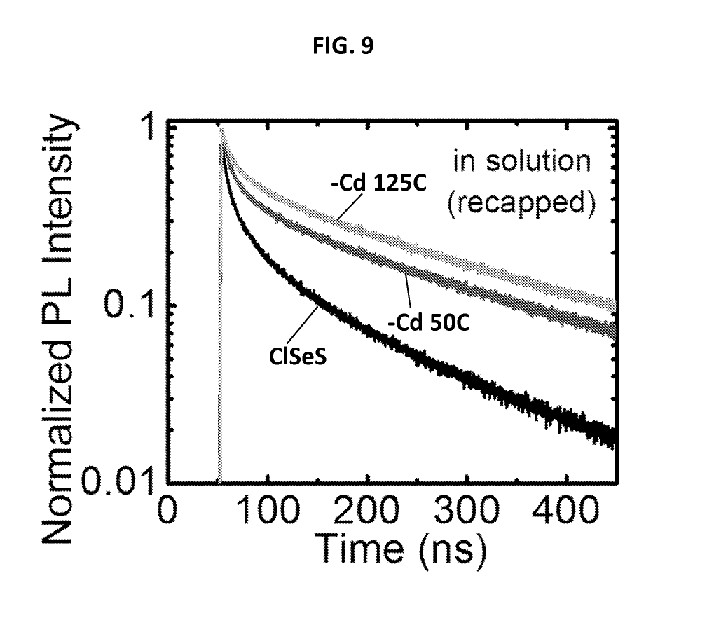

Cation exchange dramatically increases the PL QY and improves stability of the ceQDs. A type I heterojunction (i.e., a straddling gap) is formed during cation exchange to form an outer cation-exchanged layer. Charge carriers (electrons and holes) have a longer lifetime in a ceQD comprising a core and an outer cation-exchanged layer. Photoexcited electrons and holes are initially isolated in the ceQD core, but eventually pass through the outer cation-exchanged layer to reach the metal oxide (e.g., TiO₂) film or electrolyte. In some examples, Cd-exchanged CuInSeₓS₂₋ₓ QDs including a high percentage of selenium anions (i.e., about 70% Se anions) have an increased PL QY that is more than 50-fold greater than non-exchanged CuInSeₓS₂₋ₓ QDs (see, e.g., FIG. 8). The PL lifetime is also increased (see, e.g., FIG. 9) as a faster PL decay component disappears to leave only a long component. In some embodiments, the PL lifetime is increased by more than 4-fold compared to corresponding QDs lacking an outer cation-exchanged layer. PL intensity and lifetime increases as the extent of cation exchange increases. Without wishing to be bound by a particular theory, the combination of increased QY and suppression of a fast decay component is consistent with a reduction in surface traps through inorganic passivation.

During synthesis, QDs typically include long-chain surface capping ligands, e.g., oleic acid, oleate, 1-dodecanethiol, oleylamine. These long-chain ligands may suppress charge transfer from/to QDs, and also inhibit penetration into a mesoporous metal oxide film when fabricating a photoanode. Thus, it may be desirable to replace the long-chain surface ligands with smaller surface molecules such as amines (see, e.g., Fuke et al., U.S. Patent Publication No. 2012/0103404, which is incorporated herein by reference).

In some embodiments, the ceQDs are subsequently recapped (i.e., the long-chain ligands are replaced) with a short-chain amine, such as a C2-C6 primary amine. In some examples, the ceQDs were capped with t-butylamine. Capping with a short-chain amine decreases the ceQD's hydrodynamic radius and facilitates subsequent infiltration into pores of a metal oxide film, such as TiO₂, thereby increasing the surface density of ceQDs on the film. Short-chain amine capping provides increased attachment to the metal oxide film without using a bifunctional linker to covalently bind the ceQDs to the metal oxide.

Thus, in one embodiment, the ceQDs comprise a core, an outer cation-exchanged layer having a cation composition that differs from a cation composition of the core, and a plurality of capping ligands having a formula RNH₂ where R is C2-C6 alkyl. In another embodiment, the ceQDs consist essentially of a core, an outer cation-exchanged layer having a cation composition that differs from a cation composition of the core, and a plurality of capping ligands having a formula RNH₂ where R is C2-C6 alkyl. In yet another embodiment, the ceQDs consist of a core, an outer cation-exchanged layer having a cation composition that differs from a cation composition of the core, and a plurality of capping ligands having a formula RNH₂ where R is C2-C6 alkyl. In any of the above embodiments, the outer cation-exchanged layer may be a monolayer.

B. Photoanodes and Solar Cells with Cation-Exchanged Quantum Dots

Embodiments of the disclosed ceQDs are suitable for use in photovoltaic devices, such as solar cells. In some embodiments, the solar cell is a QDSSC, such as the exemplary QDSSC 10 illustrated in FIG. 1. QDs 40 are attached to the surface of a porous metal oxide film 20, supported on a transparent, electrically conducting substrate 30, e.g., FTO-coated glass. The QDs, metal oxide film, and substrate together form a photoanode.

In some embodiments, the metal oxide film 20 has a thickness of 1 μm to 30 μm, such as a thickness of 10-15 μm. In some embodiments, the metal oxide film comprises a transition metal. Suitable metal oxide films include, but are not limited to, TiO₂, SnO₂, ZrO₂, ZnO, WO₃, Nb₂O₅, Ta₂O₅, BaTiO₂, SrTiO₃, ZnTiO₃, CuTiO₃, and combinations thereof. In certain embodiments, the metal oxide film is TiO₂.

The metal oxide film may be a mesoporous metal oxide, such as mesoporous TiO₂. In some embodiments, the mesoporous metal oxide has an average pore size of 20-50 nm, such as 20-40 nm, or 30 nm. In certain embodiments, the metal oxide film comprises a first, light-absorbing layer mesoporous metal oxide particles having a diameter of 10 to 40 nm, such as 15-25 nm or 20 nm, and a second, light-scattering layer comprising metal oxide particles having a diameter of 100 to 600 nm, such as, 200-500 nm, 300-500 nm or 400 nm. The light-absorbing layer may have a thickness from 1 to 30 μm, such as 5 to 20 μm or 10 to 15 μm. The scattering layer may have a thickness form 1 to 10 μm, such as 4 to 6 μm, or 5 μm. The scattering layer functions to scatter or reflect non-absorbed photons in the light-absorbing layer so they may remain in the QDSSC and be absorbed by QDs rather than passing through the QDSSC unabsorbed. Thus, in some embodiments, the scattering layer increases absorption and power conversion efficiency. In one example, the metal oxide film included a first layer comprising mesoporous 20 nm TiO₂ particles and having a thickness of 10 μm, and a second layer comprising 400 nm TiO₂ particles and having a thickness of 5 μm.

In some embodiments, the surface density of quantum dots 40 on the metal oxide film 20 is increased when cation-exchanged quantum dots are capped with a ligand comprising a short-chain amine prior to attachment to the metal oxide. For example, absorbance of a quantum dot-sensitized metal oxide film may be up to 2-3× greater when the QDs are capped with a short-term amine. The ligand may have a formula RNH₂ where R is C2-C6 alkyl. In certain embodiments, the ligand is t-butylamine.

The solar cell further includes a hole-extracting and hole-transporting material 50 and a counter electrode 60. The hole-extracting and hole-transporting material is in contact with both the QD-sensitized TiO₂ and the counter electrode. Suitable hole-extracting and hole-transporting materials, such as liquid and solid state electrolytes, include sulfide, polysulfide, cobalt complex, spiro-OMeTAD (2,2′,7,7′-tetrakis-(N,N-di-p-methoxyphenylamine)-9,9′-spirobifluorene), and iodide electrolytes. In some embodiments, the hole-extracting and hole-transporting material is a polysulfide electrolyte. The polysulfide electrolyte may be a solution comprising a solvent selected from water, an organic solvent, or a combination thereof. In some embodiments, the organic solvent is a lower alkyl alcohol, i.e., a C1-C10 alcohol, such as methanol or ethanol. In certain examples, the electrolyte was aqueous 1M Na₂S, 1M S. In other examples, the electrolyte was an aqueous-methanol mixture saturated with Na₂S and S with a 1:1 ratio. Exemplary counter electrodes include Cu_{y}S/FTO (0.5<y<2) and Pt-FTO.

Chemical incompatibility with the most commonly used polysulfide electrolyte typically necessitates post treatment of untreated QD-sensitized films by depositing ZnS onto the QD-sensitized film using a selective ion layer reaction (SILAR) for higher efficiency QDSSCs, especially for Se-chalcogenide sensitizers. However, while a conformal ZnS layer formed by SILAR is an effective chemical barrier, it also reduces recombination between electrons in QDs with holes in the electrolyte. Because embodiments of the disclosed ceQDs are stable when exposed to a polysulfide electrolyte, the time-intensive SILAR step becomes unnecessary. Nonetheless, in some embodiments a ceQD-sensitized film may be post treated with ZnS using SILAR. Following ZnS deposition, the film may be heated, e.g., to 300° C. for 1-5 minutes.

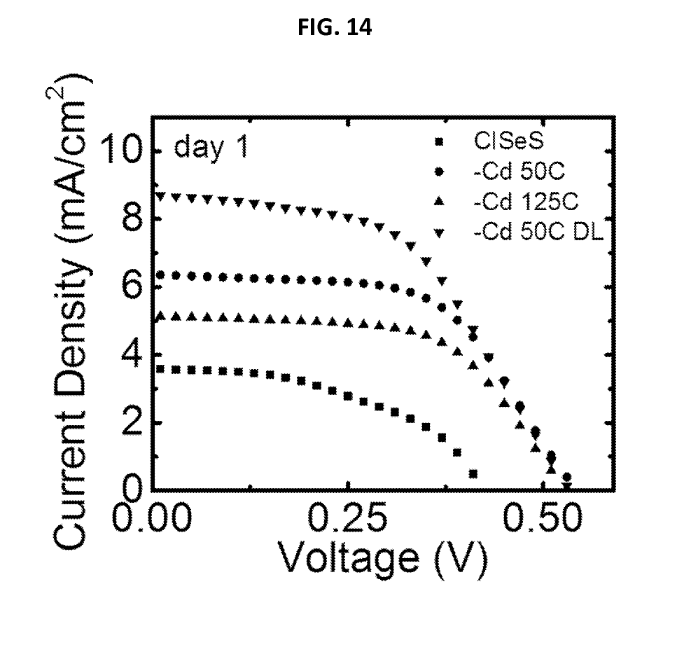

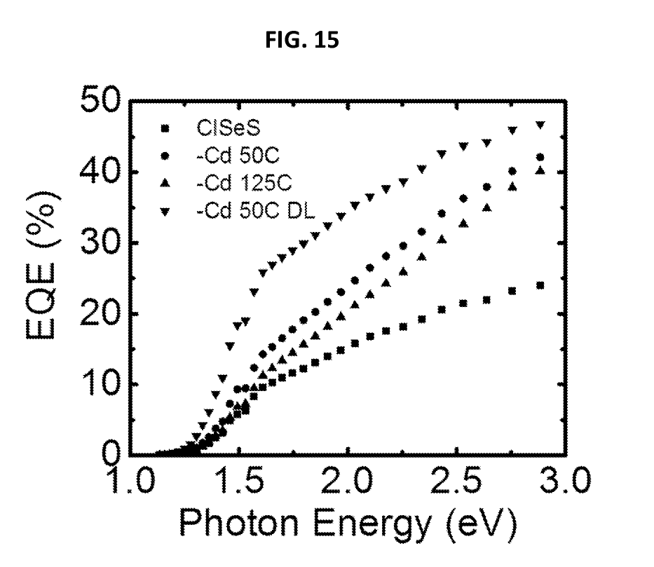

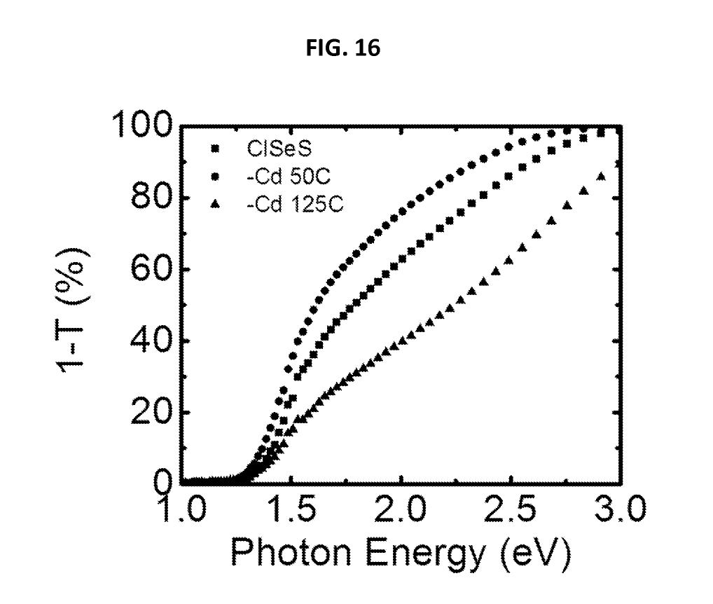

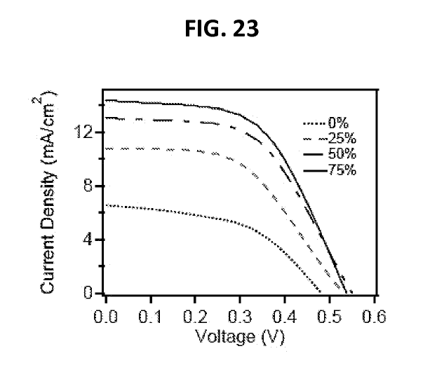

Embodiments of the disclosed QDSSCs have a current density ≧5 mA/cm² over a voltage range from 0.0-0.6 V, such as a current density from 5-30 mA/cm², or 5-20 mA/cm² (FIGS. 14, 23). Although QDs that were treated (cation-exchanged) at higher temperatures (e.g., at 125° C.) had a greater normalized PL intensity in solution, ceQDs that were treated at lower temperatures (e.g., at 50° C.) had a greater current density (FIG. 14), greater external quantum efficiency (FIG. 15), and greater light absorption (FIG. 16). In one example, current density was further increased when a scattering TiO₂ layer was added before the ceQDs were attached to the photoanode (FIG. 14, indicated as “DL”). The light absorbing layer consisted of 20 nm TiO₂ particles and had a thickness of 10 μm. The scattering layer consisted of 400 nm TiO₂ particles and had a thickness of 5 μm. The increased open-circuit voltage V_{oc} for devices fabricated with cation-exchanged quantum dots is attributed to reduced recombination, while the increased photocurrent is provided by the enhanced charge extraction efficiency from the ceQDs.

A power conversion efficiency (PCE) up to 25% may be achievable for a QDSSC including embodiments of the disclosed ceQDs. Some embodiments of the disclosed QDSSCs have a PCE>1%, >2%, >3%, 1-10%, 1.5-7%, 2-7% or 2-5%. In one example, the QDSSC had a PCE of 3.5%. In another example, the QDSSC had a PCE of 5.1%. In comparison, the best performance from a QDSSC with untreated (i.e. no cation exchange) CuInSeₓS₂₋ₓ QDs was 0.72%.

Device stability can be particularly difficult to achieve in QDSSCs due to limited chemical compatibility of the QDs with known electrolytes. However, some embodiments of the disclosed QDSSCs incorporating ceQDs exhibit unexpectedly superior material stability compared to QDSSCs incorporating untreated QDs. These results were unexpected since it is the anion that typically determines the chemical stability of semiconductors. In the disclosed embodiments, the anion remains the same, and only the cation composition has changed. In one example, QDSSCs with QDs that had undergone cation exchange with Cd showed stable or improved performance after several days to several weeks, whereas a QDSSC with untreated CuInSeₓS₂₋ₓ QDs showed essentially no photo-response (FIG. 16). QDSSC performance (e.g., efficiency) may remain stable for more than 24 hours, such as more than 72 hours, more than one week, more than two weeks, more than one month, more than 6 months, more than one year, or even up to 20 years. In some examples, QDSSC performance remained stable after 96 hours.

### III. METHODS OF MAKING CATION-EXCHANGED QUANTUM DOTS

Embodiments of QDs comprising CuInSeₓS₂₋ₓ are synthesized by combining copper, indium, selenium, and sulfide precursors to form nucleated CuInSeₓS₂₋ₓ particles. The reaction is allowed to proceed at a temperature of 220° C. to 240° C. for an effective period of time, such as 10-100 minutes to produce colloidal CuInSeₓS₂₋ₓ QDs (0<x<2) having an average diameter from 1-20 nm. As time increases, the average diameter increases. In certain embodiments, the time is 10-30 minutes, and QDs with an average diameter from 2-6 nm (±10%) are produced.

Cation exchange is performed by exposing QDs to a solution comprising one or more metal cations, M. In some embodiments, M is Cd, Zn, Sn, Ag, Au, Hg, Cu, In, or a combination thereof. Factors influencing the extent of cation exchange include the concentration of metal cations, the reaction temperature, the reaction time, the reactivity of M complexes, and combinations thereof.

The colloidal QDs are dispersed in a suitable solvent, and a solution comprising metal cations for exchange is combined with the quantum dot suspension. The solvent and metal cation solution are selected so that they are mutually soluble. In certain examples, the metal cations were provided as a metal oleate solution. Metal cations also may be provided as a metal-phosphonic acid, metal-organic (e.g., dimethyl-cadmium, diethyl zinc), metal carboxylate (e.g., metal stearate), or metal salt (e.g., CdCl₂) solution. In some instances, such as when the cation solution is a metal salt solution, the QDs may be recapped with a short-chain ligand (e.g., a short-chain amine such as t-butylamine) before cation exchange is performed.

Cation exchange is performed at temperatures ranging from ambient to 200° C. for an effective period of time. In some embodiments, the temperature was in the range of 20-150° C., such as from 50-150° C. As temperature increases, the extent of cation exchange increases. The temperature also may influence selectivity of cation exchange. For example, when cation exchange with Cd was performed on CuInSeₓS₂₋ₓ QDs, indium was selectively exchanged at lower temperatures (e.g., ˜50° C.), whereas copper and indium were both exchanged at higher temperatures (e.g., ≧75° C.). The effective period of time depends in part on the cation concentration and the reaction temperature. In some embodiments, the effective period of time is 1 to 60 minutes, such as 5 to 15 minutes or 8 to 12 minutes. In certain examples, cation exchange was performed for 10 minutes using a cation solution comprising 0.5M cadmium oleate.

### IV. METHODS OF MAKING QDSSCS

Embodiments of the disclosed QDSSCs have a two-electrode sandwich cell configuration similar to a standard dye-sensitized solar cell. The photoanode is prepared by first depositing a nanocrystalline metal oxide film, such as a mesoporous TiO₂ film, onto a substrate such FTO-coated glass. The mesoporous TiO₂ film can be prepared by screen-printing a TiO₂ paste, which is subsequently heated to 500° C. in air to evaporate solvent, burn out organics in the paste, and sinter the TiO₂ particles. The film then is sensitized by soaking as in a quantum dot suspension comprising ceQDs as described herein. The film is soaked in the ceQD suspension for several hours to several days. In some examples, the film was soaked in a ceQD suspension for 24 hours. In other examples, the film was soaked in a ceQD suspension for 36 hours. In certain embodiments, amine-capped (e.g., t-butylamine capped), ceQDs are used to facilitate attachment to the film, thereby increasing the surface area density of ceQDs on the film.

The cell is constructed by placing the photoanode and a counter electrode (e.g., Cu_{y}S/FTO glass, 0.5<y<2) together, separated by a spacer, and sealing the cell. The space between the electrodes is filled with a suitable electrolyte. In some examples, the electrolyte was a polysulfide electrolyte, e.g., aqueous 1M Na₂S, 1M S, or an aqueous-methanol mixture saturated with Na₂S and S with a 1:1 ratio.

### V. EXAMPLES

General Procedures:

Reactions were carried out in a standard Schlenk line under argon atmosphere. Technical grade oleylamine (70%), technical grade trioctylphosphine (TOP) (90%), technical grade 1-octadecene (90%), technical grade oleic acid (90%), 1-dodecanethiol (98%), tert-butylamine (98%), CdO (99.5%), Se powder (99.99%), indium acetate (In(III) (Ac)₃) (99.99%), copper iodide (Cu(I)I) (99.5%), anhydrous methanol (99.8%), anhydrous acetone (99.8%), anhydrous octane (99.9%), and anhydrous chloroform (99.9%) were obtained from Sigma Aldrich. Materials were used as received.

Quantum Dot Synthesis: CuInSeₓS₂₋ₓ QDs were synthesized similarly to the Li et al. method (J Am Chem Soc 2011, 133 (5), 1176-1179). Briefly, 1 mmol of CuI and 1 mmol of indium acetate were added to 5 ml of 1-dodecanethiol (DDT) and 1 ml of oleylamine and degassed at 100° C. for 30 minutes in a 50 ml flask. The solution was heated to 130° C. until it became yellow and transparent, and then degassed again for 30 minutes at 100° C. The temperature was then set to 230° C.; once it reached 220° C., a syringe pump was used to inject 2M TOP-Se slowly into the flask as it continued to heat up during quantum dot nucleation and growth. After some period of time, typically 10-30 minutes, the reaction was cooled and the QDs were cleaned by dissolving in chloroform and precipitation with methanol. The QDs were stored in 5 ml of octane following cleaning. The synthesis typically results in 90%+chemical yield of QDs (relative to the copper and indium precursors).

Cation Exchange: For cation exchange with Cd or Zn, a stock solution of 0.5M cadmium or zinc oleate was prepared with 3:1 oleic acid:Cd/Zn dissolved in octadecene (ODE). 4 ml of the cleaned QDs in octane solution (˜50 mg/ml) were added to 4 ml of 0.5M cadmium or zinc oleate solution and set to 50-150° C. depending on the desired degree of cation exchange. Cation exchange was performed for 10 minutes unless otherwise noted.

Quantum Dot Recapping with t-Butylamine: QDs were cleaned twice as follows. The QDs were dissolved in chloroform, and acetone was added to precipitate the QDs. The QDs were centrifuged, and redissolved in chloroform. Methanol was added to precipitate the QDs. Precipitated QDs were collected by centrifugation. In one method, the QDs were redissolved in chloroform, and then recapped with t-butylamine (tBA) at a concentration of approximately 0.05 g/ml by stirring for 24 hours in a 50:50 tBA:chloroform solution. The tBA-capped QDs were precipitated by adding methanol (about 3:1 methanol:tBA), and centrifuged. In another method (the “0 hr” exposure), the QDs were recapped by dissolving precipitated QDs in tBA at a concentration of approximately 0.05 g/ml, and then precipitating by adding methanol (about 3:1 methanol:tBA), and centrifuged. Following centrifugation, the supernatant was discarded, and the QDs were dissolved in the same amount of tBA again. The solution was sonicated for a few minutes. Methanol was added to precipitate the tBA-capped QDs, and the QDs were collected by centrifugation. In both methods the tBA-capped QDs were dissolved in octane (approximately 0.05 g/ml), and the solution was centrifuged at very high rpm (e.g., 20,000 rpm for 30 minutes) to remove aggregates that formed during recapping. Any precipitate was discarded. The QD-octane supernatant was diluted with octane to an absorbance of about 0.2 (approximately 0.01 g/ml) at the 1S absorption peak (typically 850 nm), and used to prepare QD-sensitized mesoporous (mp) TiO₂ films.

Preparation of QD-Sensitized Solar Cells: Mesoporous (mp) TiO₂ films, 10-15 μm thick, on fluorinated tin oxide-coated glass were sensitized by soaking in diluted QD octane solutions for 24 hours. The films were then rinsed with chloroform or octane. The counter electrode was fabricated by thermally evaporating 100 nm of Cu onto a fluorinated tin oxide (FTO) coated glass substrate to form Cu_{y}S/FTO (0.5<y<2) which was subsequently immersed in an aqueous polysulfide electrolyte for 15 min to form Cu_{y}S/FTO. The device was completed using a 40-50 μm Surlyn spacer (DuPont) and sealed by heating the polymer frame. The cell was filled with a polysulfide electrolyte (aqueous 1M Na₂S, 1M S and/or aqueous-methanol mixture saturated with Na₂S and S with a 1:1 ratio).

Characterization:

Transmission electron microscopy (TEM): Transmission electron microscopy (TEM) samples were prepared on Cu grids (obtained from Ted Pella) with a thin carbon film on a holey carbon support from a dilute solution of QDs in chloroform. TEM analysis was carried out with a JEOL 2010 TEM operating at 200 kV.

Scanning electron microscopy (SEM) and x-ray dispersive spectroscopy (EDX): Scanning electron microscopy (SEM) samples were prepared by breaking a QDSSC anode in half, then the cross-section was analyzed using a Quanta 400 FEG from FEI Company. The electron beam was scanned across the cross-section and the energy and count of X-rays were analyzed to produce an EDX scan.

Absorption and photoluminescence (PL) spectroscopy: All optical measurements of QDs in solution were performed in either chloroform or octane using a quartz or optical glass cuvette. UV-vis absorption spectra were obtained with Agilent 8453 photodiode array spectrometer. Visible static PL was measured on a Horiba-Yvon Fluoromax 4 with 500 nm excitation. Time resolved PL was measured on the same Horiba-Yvon Fluoromax 4 with a pulsed 455 nm LED excitation. Near-IR PL measurements were performed under 808 nm diode laser excitation using a liquid N₂ cooled InSb detector with a grating monochromator. The excitation was mechanically chopped and the signal was enhanced with a lock-in amplifier.

Solar cell characterization: The EQE measurements were performed using QE/IPCE Measurement Kit equipped with 150 W Xe lamp (no. 6253, Newport) as a light source and Oriel Cornerstone monochromator. The light intensity was adjusted with a series of neutral density filters and monitored with a Newport optical power meter 1830C power meter with a calibrated Si power meter, Newport model 818 UV. The photocurrent generated by the device was measured using a Keithley 6517A electrometer. Communication between the instruments and the computer was facilitated via a GPIB interface and the instrument control and data processing were performed using software written locally in Labview. Current voltage (I-V) measurements were performed using a Keithly 2400 SourceMeter as part of a model SC01 solar cell characterization system (software and hardware) built by PV Measurements. A class ABA solar simulator (AM 1.5), also built by PV Measurements, was calibrated using a Newport-certified single crystal Si solar cell, then was used to irradiate the QDSSCs during I-V measurement. The voltage was swept from −0.1V to 0.6V at 0.01 V/step with a 1 s hold-time at each point prior to measurement. A square black mask (0.2209 cm²) was attached to the solar cells to prevent irradiation by scattered light.

### Example 1

### QDSSCs with CuInS₂ Quantum Dots

CuInS₂ QDs were made, and optionally cation-exchanged with cadmium, as described in the General Procedures.

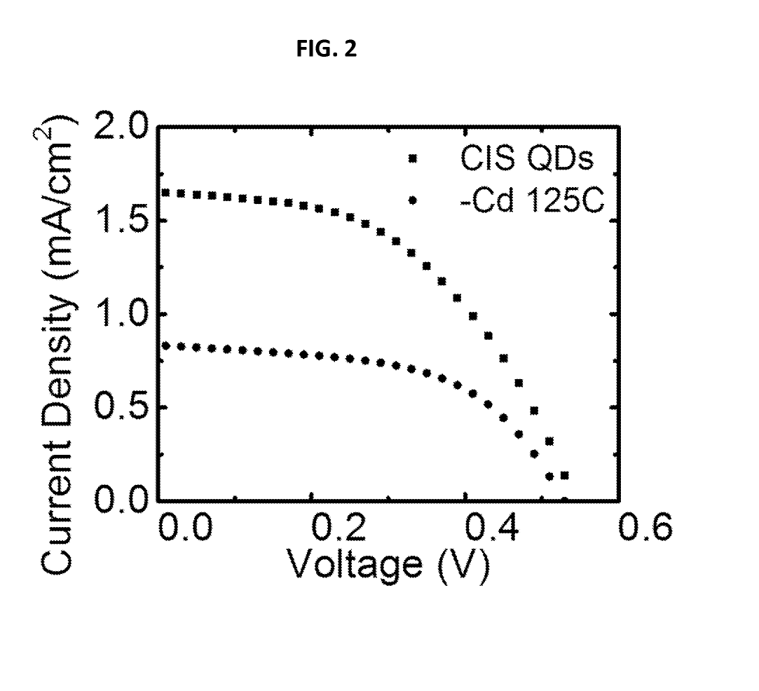

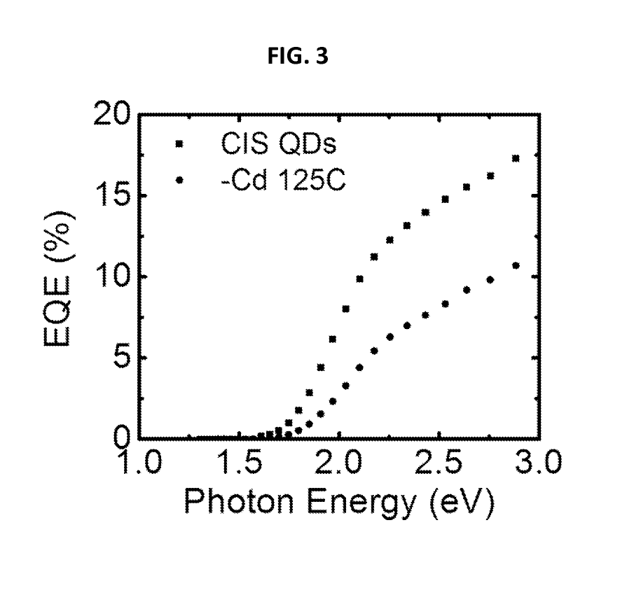

QDSSCs fabricated using CuInS₂ QDs and Cd-exchanged CuInS₂ QDs resulted in unimpressive performance (FIGS. 2 and 3), which was attributed in part to poor sunlight harvesting and a low open circuit voltage relative to the QD band gap. As the size of the CuInS₂ quantum dot sensitizers was increased, the onset of photocurrent shifted to lower photon energy without any reduction in photovoltage. This observation was not surprising because the maximum photo-voltage from a QDSSC is not set by the quantum dot band gap, but rather is set by the TiO₂ Fermi-level offset from the redox potential of the electrolyte (polysulfide).

The CuInS₂ quantum dot size was increased to reduce band gap by aging the reaction solution. This procedure was effective for achieving sizes up to ˜6 nm, corresponding to an absorption onset of ˜2.0 eV before size-distribution broadening through Ostwald ripening became apparent.

However, larger QDs present distinct disadvantages for inclusion in solar cells. It was increasingly difficult to infiltrate larger QDs into mp-TiO₂ of fixed porosity, and series resistance increased [resulting in lower fill factors (FF)] due to space charge limited transport through the electrolyte. Furthermore, as is true in all quantum dot systems, no amount of size increase can reduce the band gap further than that of the bulk material (in this case, 1.51 eV). Efficiency therefore increased to a point, but the increase was ultimately limited by inadequate larger quantum dot-loading within the mp-TiO₂ film resulting in reduced photocurrent [and not reduced photovoltage].

### Example 2

### Synthesis and Characterization of CuInSeₓS₂₋ₓ Quantum Dots

Absorption was extended to lower photon energies by forming CuInSeₓS₂₋ₓ alloyed QDs, which have the potential to reach band gaps as low as 1.0 eV (the bulk band gap of CuInSe₂). This was accomplished by adding controlled amounts of TOP-Se to the reactor during the growth of CuInS₂ QDs. TOP-Se was slowly injected into the reactor following quantum dot nucleation to form homogeneous alloyed QDs.

Since this synthesis used a large excess of anion precursors (DDT), the addition of TOP-Se did not significantly affect the growth rate, but did result in quantum dot nucleation at a lower temperature (˜180° C. for TOP-Se versus ˜220° C. for DDT) due to the increased reactivity of TOP-Se relative to DDT. Selenium was observed to comprise ˜70% of all anions (i.e., x=1.4) in the alloyed QDs based on inductively-coupled plasma-optical emission spectroscopy (ICP-OES) and energy-dispersive X-ray spectroscopy (EDX). Lower Se-content alloys can be formed by reducing the amount of added Se; however, achieving a higher Se content has proven more difficult under these reaction conditions.

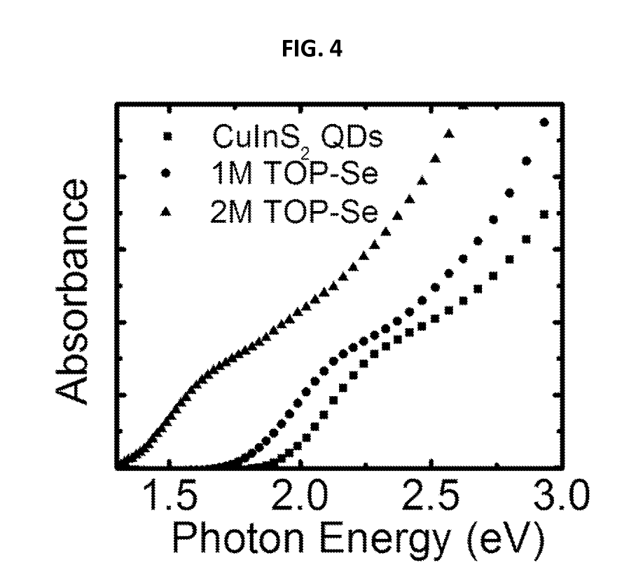

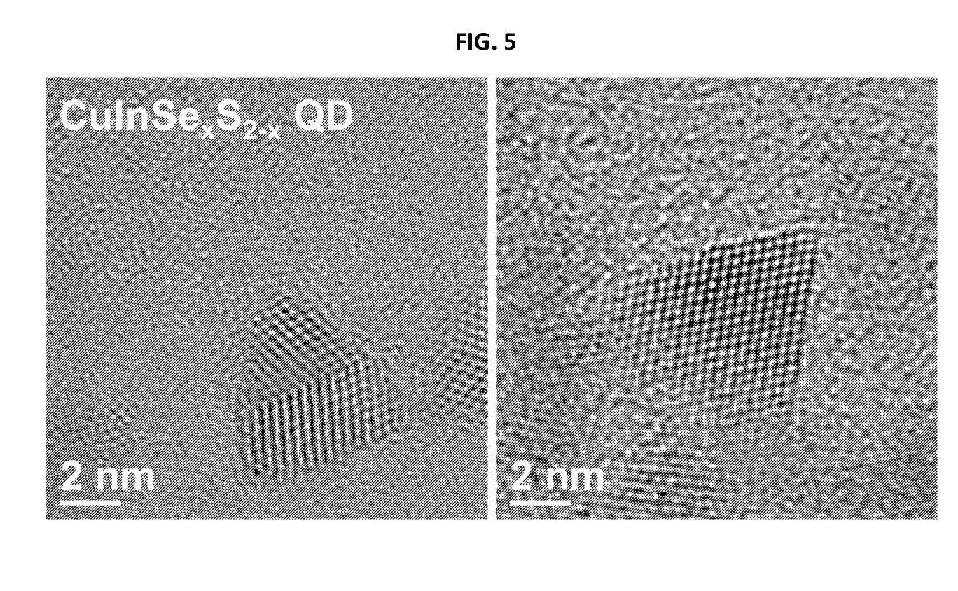

With increasing concentrations of added TOP-Se, the absorption was shifted significantly to the red (i.e., band gap was reduced, FIG. 4) for the same growth time as that used to synthesize CuInS₂ QDs. For a given size of QDs, the onset of absorption was lowered by ˜0.5 eV, the maximum expected, using this alloying strategy. Two high-resolution transmission electron microscopy TEM images of CuInSeₓS₂₋ₓ QDs are shown in FIG. 5.

### Example 3

### Synthesis and Characterization of Cation-Exchanged CuInSeₓS₂₋ₓ Quantum Dots

Mild partial cation exchange with cadmium or zinc ions was performed by exposing washed CuInSeₓS₂₋ₓ QDs to a concentrated solution of Cd-oleate or Zn-oleate at 50-150° C. for 10 minutes.

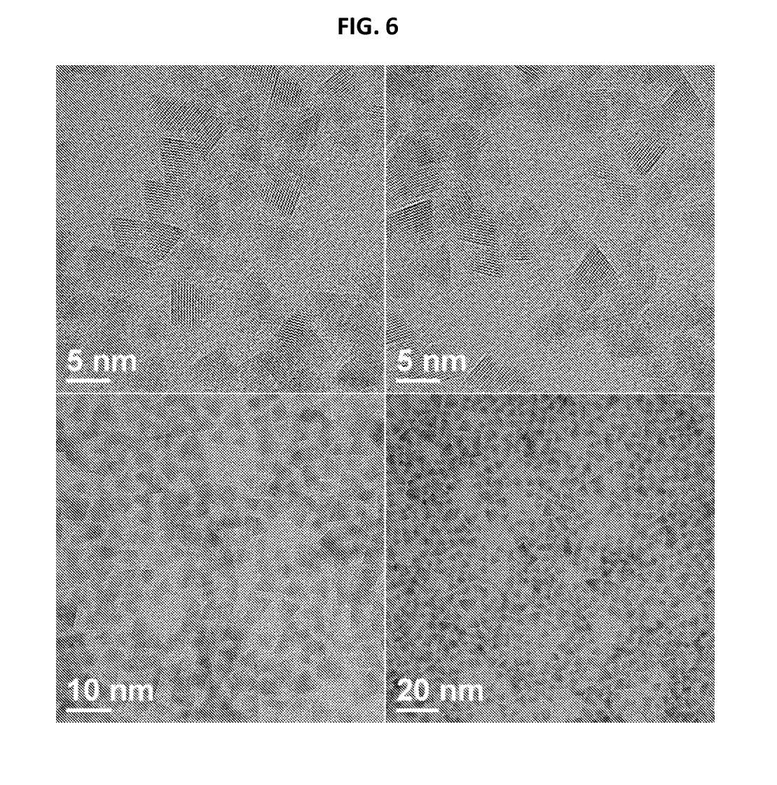

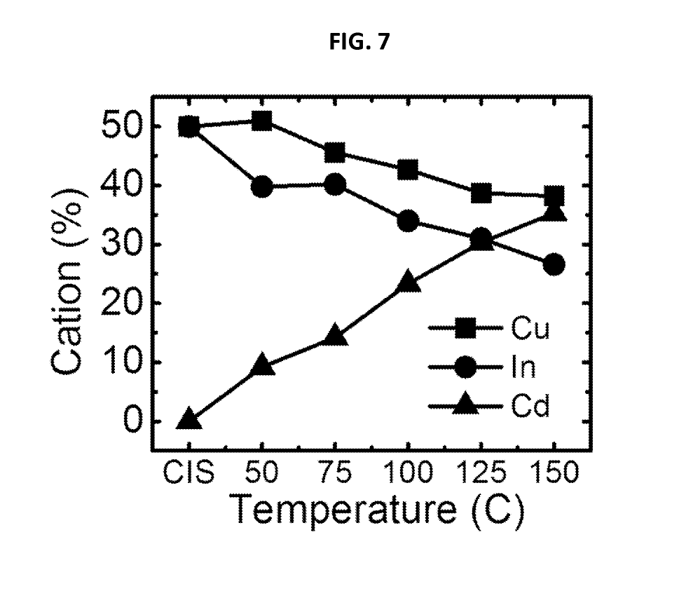

Transmission electron microscopy (TEM) images showed no change to the QD size or shape during the cadmium exchange (FIG. 6). Inductively coupled plasma measurements confirmed that as the reaction solution temperature was increased, the Cd content of the ceQDs increased while the Cu and In contents decreased (FIG. 7). At the lowest temperature (i.e., 50° C.), indium atoms, presumably at or near the quantum dot surface, were selectively replaced with Cd, but at higher temperatures Cu and In were replaced to roughly the same extent. The result was formation of a thin CdS(Se) shell≦1 nm thick.

Absorption spectra of cadmium-exchanged QDs were not significantly modified up to relatively high levels of exchange, other than a very slight blue-shift and a narrowing of the 1S exciton feature (FIG. 4) that was more pronounced for smaller QD sizes or QDs with less Se content. The almost negligible effect of the cation exchange on absorption is primarily attributed to comparable size of the ceQDs (˜5 nm) relative to the Bohr radius of CuInSe₂ (˜7.5 nm) and the thinness of the shell.

The PL QY of Cd-exchanged CuInSeₓS₂₋ₓ QDs increased dramatically, especially QDs with high Se content in which the increase was more than 50-fold. This was accompanied by a significant increase in the PL lifetime.

FIG. 8 shows the absorption and normalized PL spectra for CuInSe_{1.4}S_{0.6} QDs recapped with tert-butylamine (tBA) before and after partial cation exchange with Cd at low temperature (50° C. with 7% Cd cations) and high temperature (125° C. with 18% Cd cations). The QDs were recapped with t-butylamine. Compositions were measured with ICP using carefully calibrated standards after recapping. The normalized PL intensity (FIG. 8) and the PL lifetime (FIG. 9) of these QDs were largest with the higher temperature (125° C.) Cd-oleate exposure.

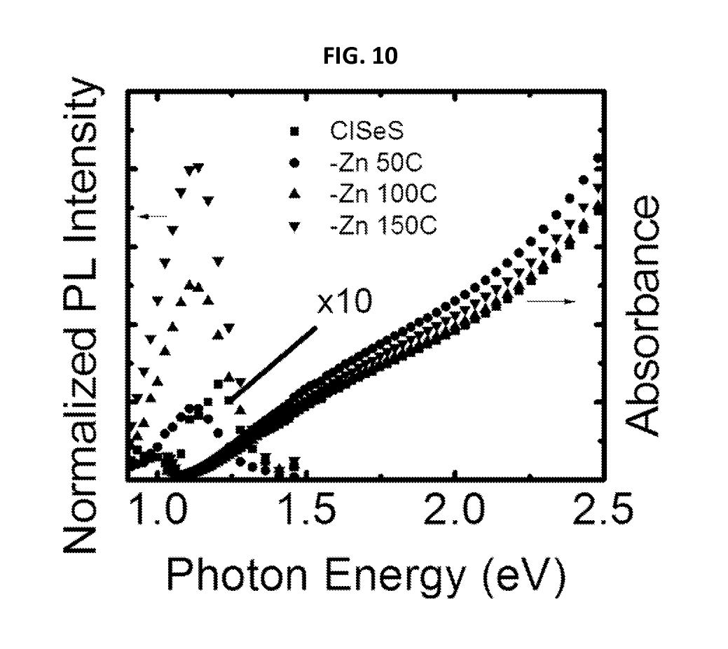

FIG. 10 shows the absorption and normalized PL spectra for CuInSe_{1.4}S_{0.6} QDs recapped with tert-butylamine (tBA) before and after partial cation exchange with Zn at 50° C., 100° C., or 150° C. The QDs were recapped with t-butylamine. The PL lifetime was larger with a lower temperature cation exchange.

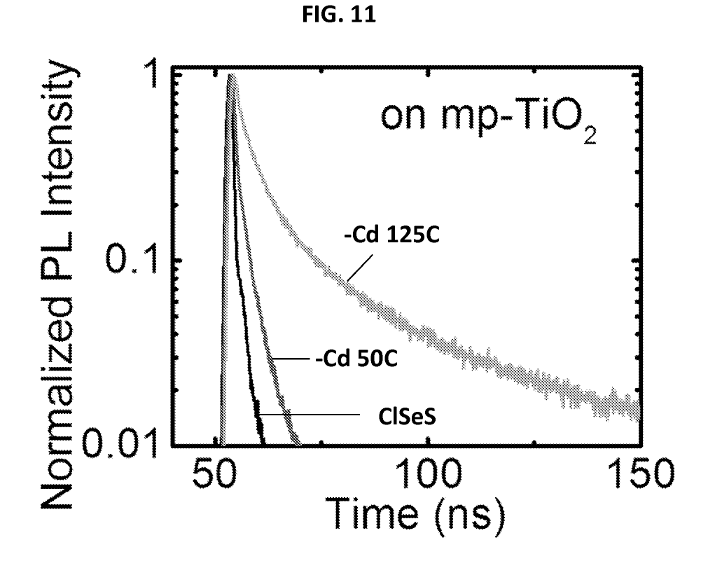

The recapped QDs were attached to a mp-TiO₂ film by 24-hour soaking in a dilute solution inside an inert-atmosphere glove box. After attachment to the TiO₂ film, PL decayed significantly faster (FIG. 11). Without wishing to be bound by a particular theory, acceleration of PL decay is primarily due to electron transfer from QDs to TiO₂. With increasing degree of cation exchange, the PL decay for QDs on mp-TiO₂ became slower, indicating the rate of electron transfer to TiO₂ decreases with increasing shell thickness. This suggests that the outer Cd(S,Se) layer passivates recombination centers, but also potentially acts as a barrier for the electron transfer to TiO₂, a tradeoff that may be mediated by control over the exact shell thickness.

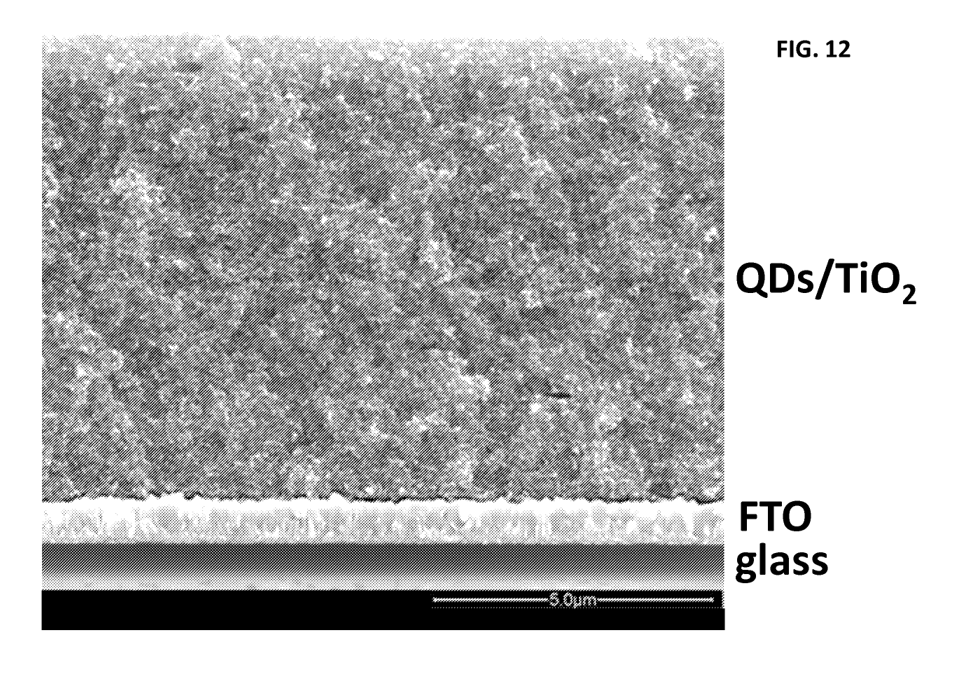

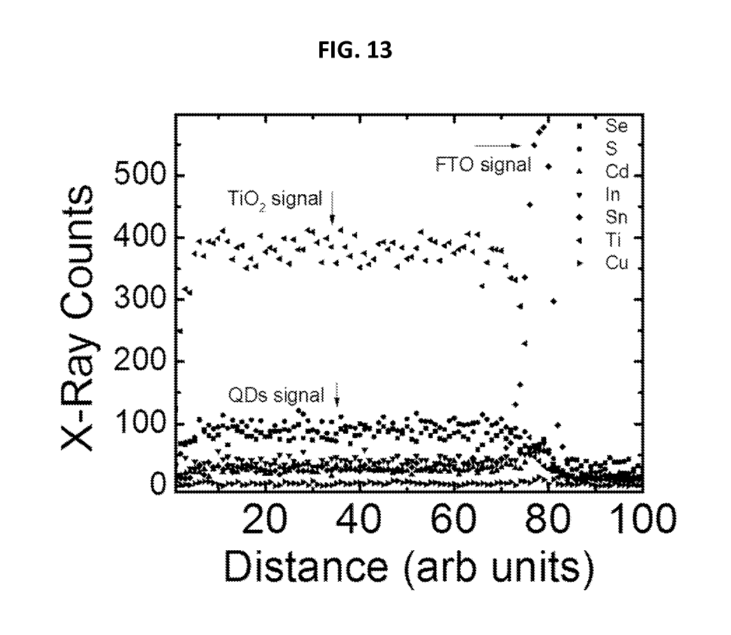

FIG. 12 is an SEM cross-section image of a QD-sensitized film on FTO-coated glass demonstrating that the pores are not completely filled by the QDs. FIG. 13 is a raw EDX line scan of the cross-section of FIG. 12 showing the uniform concentration of QDs throughout the mp-TiO₂ film.

### Example 4

### Characterization of Cation-Exchanged QDSSCs

Quantum dot-sensitized solar cells were prepared as described in General Procedures. Cells were prepared using CuInSeₓS₂₋ₓ QDs, and CuInSeₓS₂₋ₓ QDs treated by exposure to Cd-oleate or Zn oleate at 50° C., 100° C., 125° C. or 150° C. (see Example 3). One cell included a first mp-TiO₂ film and a scattering layer of TiO₂ film (10 μm of 20 nm TiO₂ particles and 5 μm of 400 nm TiO₂ particles) to increase the light path length through the device; this cell included Cd-exchanged QDs prepared at 50° C.

The QDSSCs were exposed to simulated AM1.5 sunlight. FIG. 14 is a graph of current density versus voltage measured one day after fabrication. The best performing QDSSCs included ceQDs prepared with the lower temperature Cd treatment and a 10 μm TiO₂ film. These QDSSCs reached a 2.1% efficiency, which was increased to 2.5% when an opaque scattering layer of TiO₂ film (10 μm of 20 nm TiO₂ particles and 5 μm of 400 nm TiO₂ particles) was added. The effect of the scattering layer was primarily to increase the photocurrent due to improved light harvesting (i.e. increased path length). This compared with a best performance from untreated QDs of 0.72% and with 1.9% for QDs treated at higher temperature, which had the highest/optimal normalized PL intensity in solution.

The EQE spectra of the best performing devices for each case (FIG. 15) matched closely the 1-T data for sensitized films (FIG. 16) and the absorbance of the QDs in solution (FIG. 4) indicating that the photocurrent arises from QD absorption. As shown in FIG. 16, films sensitized with ceQDs treated with Cd at lower temperature show strong absorption (due to higher QD loading), which may be a primary reason for the higher performance of these devices. Loading efficiency may be due, at least in part, to recapping with t-butylamine. It has been qualitatively observed that amines preferentially replace thiols or carboxylates on the CuInSeₓS₂₋ₓ QD surface, while amines are generally thought to bind only weakly to CdSe, which could help explain this effect since the QD surface becomes increasingly composed of Cd(Se,S) during the cation exchange at higher temperatures and/or for longer times.

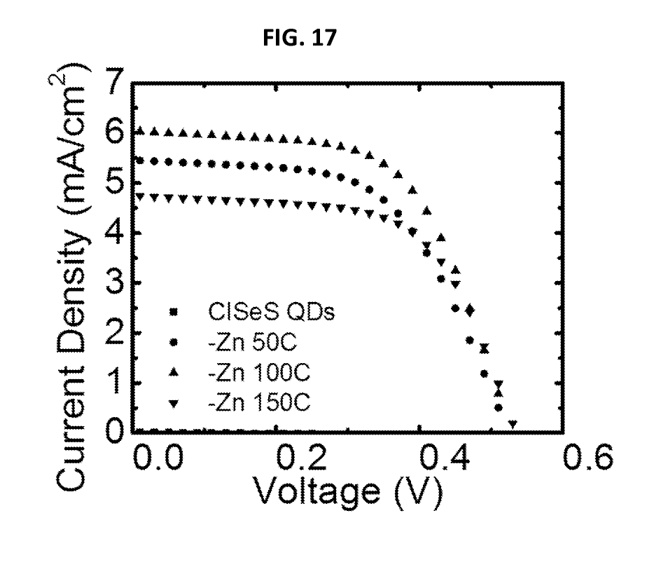

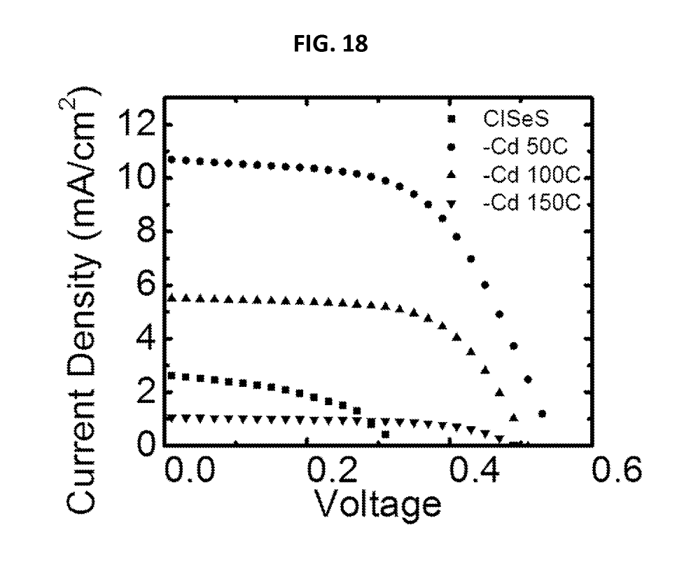

FIG. 17 is a graph of current density versus voltage for QDSSCs including CuInSe_{1.4}S_{0.6} QDs that were cation-exchanged with Zn at 50° C., 100° C., or 150° C. FIG. 18 is a graph of current density versus voltage for QDSSCs including CuInSe_{1.4}S_{0.6} QDs that were cation-exchanged with Cd at 50° C., 100° C., or 150° C. FIGS. 17 and 18 demonstrate that low-temperature cation exchange with Cd produced the largest short-circuit current density. These QDSSCs show improved performance relative to the devices characterized in FIG. 14, in part due to improvements in the electrolyte (i.e. adding methanol).

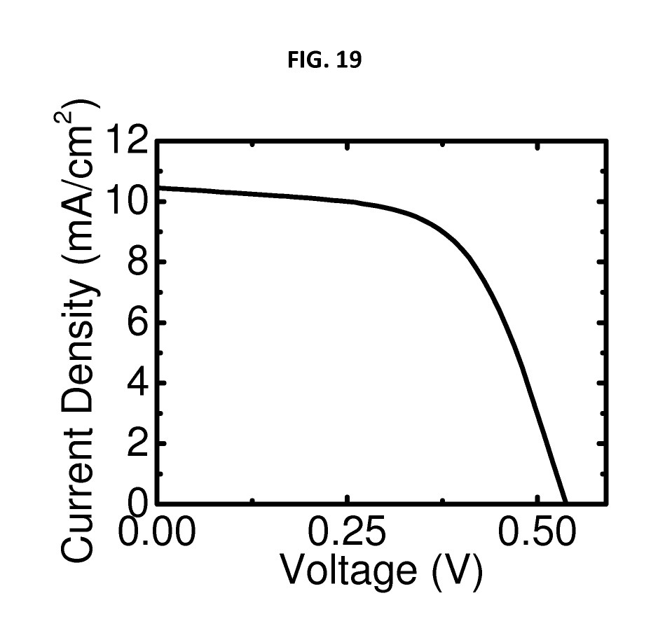

Another QDSSC was fabricated using a batch of similar QDs treated with Cd-oleate at 50° C., having a slightly smaller band gap, incorporating the second scattering TiO₂ layer, and a moderately improved counter electrode (with reduced series resistance). The QDSSC was demonstrated to have an efficiency of 3.5% (FIG. 19). The increased V_{oc} (0.55 V vs. 0.42 V) for devices fabricated with Cd-treated QDs is attributed to reduced recombination, while the increased photocurrent (6.8 mA/cm² vs. 3.6 mA/cm²) is explained by the enhanced charge extraction efficiency (due to slower recombination) from the treated QDs.

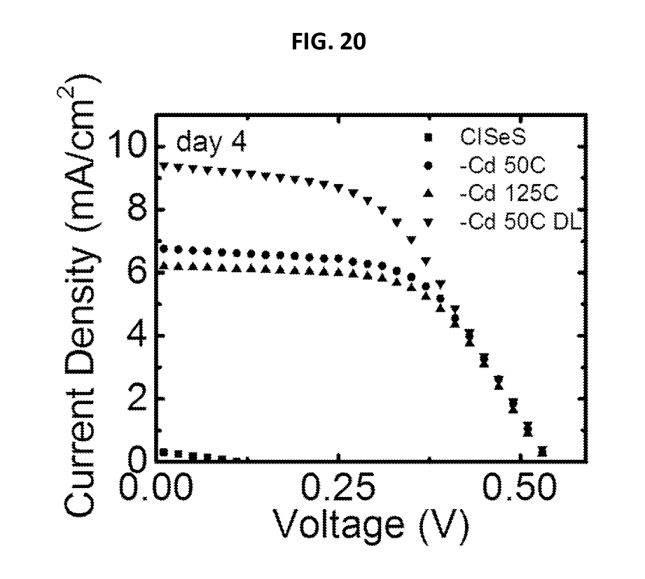

Devices fabricated with QDs that had undergone Cd-treatment improved modestly over four days (FIG. 20) while the devices fabricated with untreated CuInSeₓS₂₋ₓ QDs became significantly worse showing essentially no photo-response. The improvement in performance over time may be due to a capillary effect of slow electrolyte permeation of the TiO₂ pores. This effect should also be present in untreated CuInSeₓS₂₋ₓ QDSSCs; however, anodic corrosion in the presence of the polysulfide electrolyte (e.g. anion exchange of Se with S) likely produced the dramatic reduction in photocurrent and voltage seen in devices fabricated with untreated QDs.

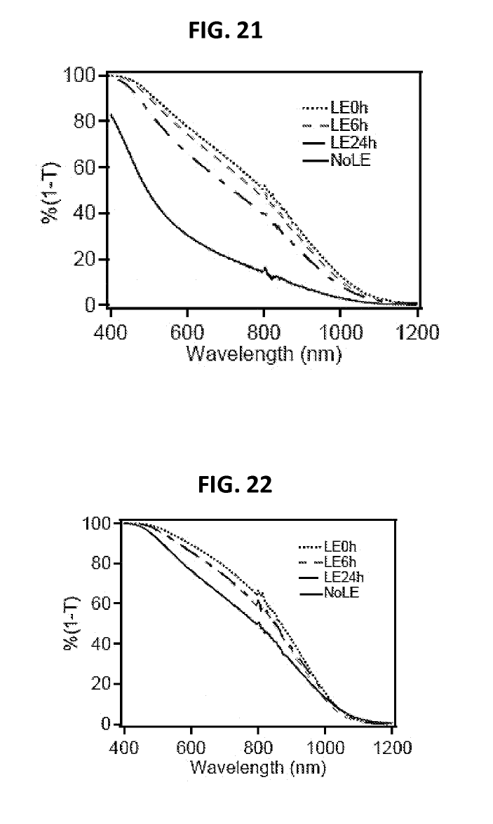

The effect of ligand exchange time was evaluated by performing cation exchange of CuInSe_{1.4}S_{0.6} QDs with cadmium oleate at 50° C. or 125° C. for 0 hours (10 minutes) or 6 hours. FIGS. 21 and 22 show the 1-T spectra for cadmium-exchanged QD-sensitized mesoporous TiO₂ films. Cation exchange was performed at 125° C. (FIG. 21) or 50° C. (FIG. 22). FIGS. 21 and 22 demonstrate that QD loading on the TiO₂ films was increased at lower temperatures and with shorter ligand exchange times. Further characterization also demonstrated that the best results for short circuit current density (J_{sc}), open-circuit voltage (Voc), fill factor (FF), and efficiency were obtained at 50° C. with a shorter exchange time (Table 1).

TABLE 1

| Exchange | Exchange | J_{sc} | V_{oc} | | |
|---|---|---|---|---|---|
| temp. | time | (mA/cm²) | (V) | FF | Efficiency % |
| 50° C. | 0 h | 8.76 | 0.534 | 0.585 | 2.74 |
| 50° C. | 6 h | 6.70 | 0.566 | 0.590 | 2.24 |
| 125° C. | 0 h | 2.55 | 0.473 | 0.545 | 0.66 |
| 125° C. | 6 h | 2.35 | 0.524 | 0.63 | 0.77 |

### Example 5

### Characterization of QDSSCs Including Methanol in the Electrolyte

QDSSCs were constructed with various amounts of methanol and water in the electrolyte (Na₂S, S 1:1). The QDSSCs included CuInSe1.4S0.6 QDs that were cation-exchanged with cadmium at 50° C., and recapped with t-butylamine for 10 minutes.

As the concentration of methanol increased, the cell performance increased. As shown in FIG. 23, current density more than doubled as the proportion of methanol was increased from 0% to 75%. Open-circuit voltage, fill factor, and efficiency also increased (Table 2). Without wishing to be bound by a particular theory, hole transport and extraction likely are improved by methanol.

TABLE 2

| | J_{sc} | V_{oc} | | |
|---|---|---|---|---|
| Methanol | (mA/cm²) | (V) | FF | Efficiency % |
| 0% | 6.57 | 0.482 | 0.496 | 1.56 |
| 25% | 10.8 | 0.534 | 0.509 | 2.94 |
| 50% | 13.1 | 0.551 | 0.538 | 3.87 |
| 75% | 14.4 | 0.538 | 0.549 | 4.25 |

A QDSSC was constructed with CuInSe_{1.4}S_{0.6} QDs that had been cation-exchanged with Cd-oleate at 50° C., and subsequently recapped with t-butylamine using the “0 hr” exposure method. The cell had a photoanode including an FTO-glass substrate coated with silver paint at the contact point, a 10 μm layer of 20 nm TiO₂ particles with 30 nm pores, and a 5 μm layer of 400 nm TiO₂ particles. The photoanode was soaked in the ceQD solution (in octane) for 36 hours. The counter electrode was CuS on FTO-glass coated with silver paste at the contact point; a 100 nm thick copper film were deposited by a thermal evaporator, and the electrode was soaked in electrolyte. The electrolyte was saturated Na₂S:S (1:1) in 25% H₂O, 75% methanol.

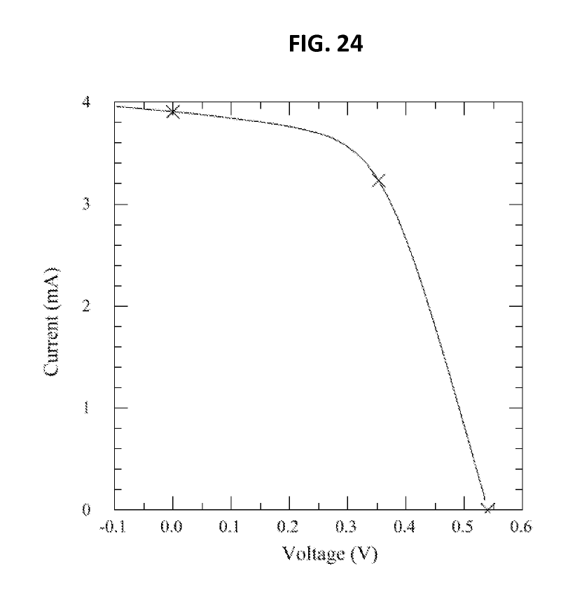

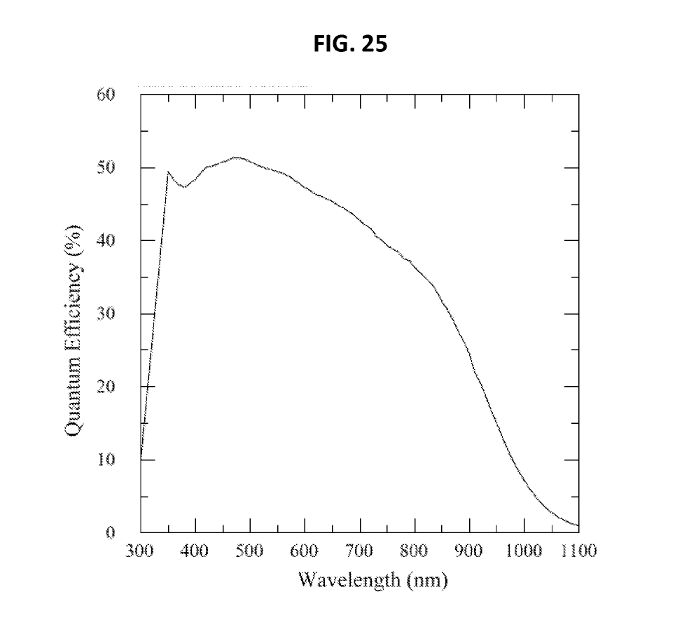

Certified data was obtained from the National Renewable Energy Laboratory (NREL). FIG. 24 is a graph of current versus voltage for the QDSSC. FIG. 25 is a graph of external quantum efficiency (light bias=1.00 mA into 0.22 cm²) versus wavelength. The QDSSC had a short-circuit current (I_{sc}) of 3.9047 mA, a short-circuit current density (J_{sc}) of 17.565 mA/cm², an open-circuit voltage (V_{oc}) of 0.5402 V, a fill factor of 0.5410, an efficiency of 5.13%, Iₘₐₓ of 3.2325 mA, Vₘₐₓ of 0.3530 V, and Pₘₐₓ of 1.1410 mW.

Embodiments of a photoanode comprise an electrically conducting substrate, a porous metal oxide film on the electrically conducting substrate, and a plurality of colloidal, cation-exchanged quantum dots on the metal oxide film, wherein the quantum dots comprise a core, an outer cation-exchanged layer having a cation composition that differs from a cation composition of the core, and a plurality of capping ligands having the formula RNH₂ where R is C2-C6 alkyl. In some embodiments, the capping ligands are t-butylamine.

In some embodiments, the core comprises a I-III-VI semiconductor and/or a I-II-IV-VI semiconductor. The I-III-VI semiconductor may be CuInSeₓS₂₋ₓ, wherein 0<x<2, or 1.3≦x≦1.7. In any or all of the above embodiments, the quantum dots may have a band gap ranging from 1.0-3.0 eV.

In one embodiment, the core comprises Cu Zn_{0.5}Sn_{0.5}SeₓS₂₋ₓ wherein 0<x<2. In another embodiment, the core comprises PbSe or PbSeₓS₁₋ₓ wherein 0≦x<1.

In any or all of the above embodiments, the outer cation-exchanged layer may comprise M cations wherein M is Cd, Zn, Sn, Ag, Au, Hg, Cu, In, or a combination thereof. In some embodiments, M is Cd or Zn.

In any or all of the above embodiments, the quantum dots may comprise a CuInSeₓS₂₋ₓ core, wherein 0<x<2, and the quantum dots may have a cation concentration comprising 1-40% M. In some embodiments, M is Cd or Zn and the quantum dot cation concentration comprises 1-20% M. In certain embodiments, the indium cations in the outer cation-exchanged layer have been replaced with Cd or Zn. In other embodiments, indium and copper cations in the outer cation-exchanged layer have been replaced with Cd or Zn.

In any or all of the above embodiments, the metal oxide may comprise a transition metal. In some embodiments, the metal oxide is TiO₂, SnO₂, ZrO₂, ZnO, WO₃, Nb₂O₅, Ta₂O₅, BaTiO₂, SrTiO₃, ZnTiO₃, CuTiO₃, or a combination thereof. In certain embodiments, the metal oxide film comprises mesoporous TiO₂.

In any or all of the above embodiments, the metal oxide film may have a thickness of 5 to 30 μm. In any or all of the above embodiments, the porous metal oxide film may include a first layer comprising mesoporous metal oxide particles having a diameter of 10 to 50 nm, and a second layer comprising metal oxide particles having a diameter of 100 to 500 nm. In some embodiments, the first and second layers comprise TiO₂. In certain embodiments, the first layer has a thickness of 1 to 30 μm and the second layer has a thickness of 1 to 10 μm.

In any or all of the above embodiments, the electrically conducting substrate may be fluorinated tin oxide on glass. In any or all of the above embodiments, the colloidal quantum dots may have the same diameter before and after undergoing cation exchange to form the outer cation-exchanged layer.

Embodiments of a device include a photoanode according to any or all of the above embodiments, a counter electrode, and a hole-extracting and hole-transporting material in contact with both the photoanode and the counter electrode. In some embodiments, the hole-extracting and hole-transporting material is a polysulfide electrolyte. The polysulfide electrolyte may be a solution comprising a solvent selected from water, a lower alkyl alcohol, or a combination thereof. In certain embodiments, the lower alkyl alcohol is methanol. In some embodiments, the counter electrode is Cu_{y}S (0.5<y<2) on fluorinated tin oxide-coated glass.

In any or all of the above embodiments, exposure of the device to simulated AM1.5 sunlight may produce a current density that remains the same or increases over a time period greater than 24 hours. In some embodiments, exposure of the device to simulated sunlight produces a current density that remains the same or increases over a time period greater than 72 hours. In some embodiments, the device produces a current density≧5 mA/cm² over a voltage range from 0-0.6 V. In some embodiments, the device has an AM1.5 power conversion efficiency (PCE) greater than 2% or ≧5%.

In one embodiment, a device comprises (i) a photoanode comprising an electrically conductive fluorinated tin oxide-coated glass substrate, a TiO₂ film comprising a layer of mesoporous TiO₂ on the substrate, and a plurality of colloidal, cation-exchanged quantum dots on the TiO₂ film, wherein the quantum dots comprise (a) a core comprising CuInSeₓS₂₋ₓ, where 1.3≦x≦1.7, (b) an outer cation-exchanged layer comprising Cd or Zn, (c) and t-butylamine capping ligands; (ii) a counter electrode comprising Cu_{y}S/fluorinated tin oxide-coated glass, wherein 0.5<y<2; and (iii) a polysulfide electrolyte in contact with both the photoanode and the counter electrode.

Embodiments of a method for making a device include (i) synthesizing colloidal quantum dots, (ii) exposing the colloidal quantum dots to a cation solution to produce cation exchange in an outer layer of the colloidal quantum dots thereby forming colloidal, cation-exchanged quantum dots comprising a core and an outer cation-exchanged layer, (iii) capping the colloidal, cation-exchanged quantum dots with a C2-C6 primary amine to form colloidal capped cation-exchanged quantum dots, (iv) providing a porous metal oxide film on an electrically conducting substrate, and (v) exposing the porous metal oxide film to the colloidal capped cation-exchanged quantum dots to produce a quantum-dot sensitized metal oxide film, thereby forming a photoanode.

In any or all of the above embodiments, the core may have a I-III-VI semiconductor, a I-II-IV-VI semiconductor composition, or a combination thereof. In some embodiments, the core comprises CuInSeₓS₂₋ₓ, wherein 1.3≦x≦1.7. In any or all of the above embodiments, the cation solution may comprise Cd, Zn, Sn, Ag, Au, Hg, Cu, and/or In cations.

In any or all of the above embodiments, synthesizing colloidal quantum dots may include combining copper, indium, selenium, and sulfide precursors to form nucleated CuInSeₓS₂₋ₓ, heating the nucleated CuInSeₓS₂₋ₓ to a temperature from 220° C. to 240° C. The reaction may proceed for an effective period of time to produce CuInSeₓS₂₋ₓ quantum dots wherein 0≦x<2.

In any or all of the above embodiments, exposing the colloidal quantum dots to a cation solution to produce cation exchange in an outer layer of the colloidal quantum dots may include dispersing the colloidal quantum dots in a solvent to produce a quantum dot suspension; combining the quantum dot suspension with the cation solution, wherein the cation solution comprises Cd, Zn, Sn, Ag, Au, Hg, Cu, and/or In cations; heating the combined quantum dot suspension and cation solution to a temperature from 50-150° C.; and maintaining the temperature for a time of 1-60 minutes. In some embodiments, the temperature and time are selected to produce partial cation exchange in the outer layer. In certain embodiments, the cation solution comprises Cd or Zn cations. In one embodiment, the cation solution comprises 0.5M cadmium oleate, the temperature is 50-125° C., and the time is 10 minutes.

In any or all of the above embodiments, the C2-C6 primary amine may be t-butylamine.

In any or all of the above embodiments, exposing the porous metal oxide film to the colloidal capped cation-exchanged quantum dots for an effective period of time may include exposing the porous metal oxide film on the electrically conducting substrate to a suspension comprising the colloidal capped cation-exchanged quantum dots for 12-48 hours.

In any or all of the above embodiments, the porous metal oxide film may comprise mesoporous TiO₂. In any or all of the above embodiments, the porous metal oxide film comprises a first layer comprising mesoporous TiO₂ particles having a diameter of 10 to 30 nm, and a second layer comprising TiO₂ particles having a diameter of 100 to 500 nm.

In any or all of the above embodiments, the method may further comprise comprising putting the photoanode in a solar cell. In some embodiments, the solar cell further comprises a counter electrode and a hole-extracting and hole-transporting material in contact with both the photoanode and the counter electrode.

In view of the many possible embodiments to which the principles of the disclosure may be applied, it should be recognized that the illustrated embodiments are only preferred examples and should not be taken as limiting the scope of the invention. Rather, the scope of the invention is defined by the following claims. We therefore claim as our invention all that comes within the scope and spirit of these claims.

1. A photoanode, comprising:
an electrically conducting substrate;
a porous metal oxide film on the electrically conducting substrate; and
a plurality of colloidal, cation-exchanged quantum dots on the metal oxide film, wherein the quantum dots comprise a core, an outer cation-exchanged layer having a cation composition that differs from a cation composition of the core, and a plurality of capping ligands having a formula RNH₂ where R is C2-C6 alkyl.

2. The photoanode of claim 1, wherein the core comprises a I-III-VI semiconductor and/or a I-II-IV-VI semiconductor.

3. The photoanode of claim 2, wherein the I-III-VI semiconductor comprises CuInSeₓS₂₋ₓ, wherein 0<x<2.

4. The photoanode of claim 3, wherein 1.3≦x≦1.7.

5. The photoanode of claim 3, wherein the quantum dots have a band gap ranging from 1.0-3.0 eV.

6. The photoanode of claim 2, wherein the core comprises CuZn_{0.5}Sn_{0.5}SeₓS₂₋ₓ wherein 0<x<2.

7. The photoanode of claim 1, wherein the core comprises PbSe or PbSeₓS₁₋ₓ wherein 0≦x<1.

8. The photoanode of claim 1, wherein the outer cation-exchanged layer comprises M cations wherein M is Cd, Zn, Sn, Ag, Au, Hg, Cu, In, or a combination thereof.

9. The photoanode of claim 8, wherein M is Cd or Zn.

10. The photoanode of claim 8, wherein the quantum dots further comprise a CuInSeₓS₂₋ₓ core, wherein 0<x<2, and the quantum dots have a cation concentration comprising 1-40% M.

11. The photoanode of claim 10, wherein M is Cd or Zn and the quantum dot cation concentration comprises 1-20% M.

12. The photoanode of claim 10, wherein indium cations in the outer cation-exchanged layer have been replaced with Cd or Zn.

13. The photoanode of claim 10, wherein indium and copper cations in the outer cation-exchanged layer have been replaced with Cd or Zn.

14. The photoanode of claim 1, wherein the capping ligands are t-butylamine.

15. The photoanode of claim 1, wherein the metal oxide comprises a transition metal.

16. The photoanode of claim 1, wherein the metal oxide is TiO₂, SnO₂, ZrO₂, ZnO, WO₃, Nb₂O₅, Ta₂O₅, BaTiO₂, SrTiO₃, ZnTiO₃, CuTiO₃, or a combination thereof.

17. The photoanode of claim 1, wherein the metal oxide film comprises mesoporous TiO₂.

18. The photoanode of claim 1, wherein the metal oxide film has a thickness of 5 to 30 μm.

19. The photoanode of claim 1, wherein the porous metal oxide film comprises a first layer comprising mesoporous metal oxide particles having a diameter of 10 to 50 nm, and a second layer comprising metal oxide particles having a diameter of 100 to 500 nm.

20. The photoanode of claim 19, wherein the first and second layers comprise TiO₂.

21. The photoanode of claim 19, wherein the first layer has a thickness of 1 to 30 μm and the second layer has a thickness of 1 to 10 μm.

22. The device of claim 1, wherein the electrically conducting substrate is fluorinated tin oxide on glass.

23. The device of claim 20, wherein the colloidal quantum dots have the same diameter before and after undergoing cation exchange to form the outer cation-exchanged layer.

24. A device, comprising:
a photoanode according to claim 1;
a counter electrode; and
a hole-extracting and hole-transporting material in contact with both the photoanode and the counter electrode.

25. The device of claim 24, wherein the hole-extracting and hole-transporting material is a polysulfide electrolyte.

26. The device of claim 25, wherein the polysulfide electrolyte is a solution comprising a solvent selected from water, a lower alkyl alcohol, or a combination thereof.

27. The device of claim 26, wherein the lower alkyl alcohol is methanol.

28. The device of claim 24, wherein the counter electrode is Cu_{y}S on fluorinated tin oxide-coated glass wherein 0.5<y<2.

29. The device of claim 26, wherein exposure of the device to simulated AM1.5 sunlight produces a current density that remains the same or increases over a time period greater than 24 hours.

30. The device of claim 29, wherein exposure of the device to simulated sunlight produces a current density that remains the same or increases over a time period greater than 72 hours.

31. The device of claim 29, wherein the device has a current density ≧5 mA/cm² over a voltage range from 0-0.6 V.

32. The device of claim 24, wherein the device has an AM1.5 power conversion efficiency (PCE) greater than 2%.

33. The device of claim 32, wherein the PCE is ≧5%.

34. A device, comprising:
a photoanode comprising
an electrically conductive fluorinated tin oxide-coated glass substrate,
a TiO₂ film comprising a layer of mesoporous TiO₂ on the substrate, and
a plurality of colloidal, cation-exchanged quantum dots on the TiO₂ film,
wherein the quantum dots comprise (a) a core comprising CuInSeₓS₂₋ₓ, where 1.3≦x≦1.7, (b) an outer cation-exchanged layer comprising Cd or Zn, (c) and t-butylamine capping ligands;
a counter electrode comprising Cu_{y}S/fluorinated tin oxide-coated glass wherein 0.5<y<2; and
a polysulfide electrolyte in contact with both the photoanode and the counter electrode.

35. A method for making a device, the method comprising:
synthesizing colloidal quantum dots;
exposing the colloidal quantum dots to a cation solution to produce cation exchange in an outer layer of the colloidal quantum dots thereby forming colloidal, cation-exchanged quantum dots having a core and an outer cation-exchanged layer;
capping the colloidal, cation-exchanged quantum dots with a C2-C6 primary amine to form colloidal capped cation-exchanged quantum dots;
providing a porous metal oxide film on an electrically conducting substrate; and
exposing the porous metal oxide film to the colloidal capped cation-exchanged quantum dots to produce a quantum-dot sensitized metal oxide film, thereby forming a photoanode.

36. The method of claim 35, wherein the core has a I-III-VI semiconductor, I-II-IV-VI semiconductor composition, or a combination thereof.

37. The method of claim 35, wherein the core comprises CuInSeₓS₂₋ₓ, wherein 1.3≦x≦1.7.

38. The method of claim 35, wherein the cation solution comprises Cd, Zn, Sn, Ag, Au, Hg, Cu, and/or In cations.

39. The method of claim 35, wherein synthesizing colloidal quantum dots comprises:
combining copper, indium, selenium, and sulfide precursors to form nucleated CuInSeₓS₂₋ₓ;
heating the nucleated CuInSeₓS₂₋ₓ to a temperature from 220° C. to 240° C.; and
allowing the reaction to proceed for an effective period of time to produce CuInSeₓS₂₋ₓ quantum dots wherein 0≦x<2.

40. The method of claim 35, wherein exposing the colloidal quantum dots to a cation solution to produce cation exchange in an outer layer of the colloidal quantum dots comprises:
dispersing the colloidal quantum dots in a solvent to produce a quantum dot suspension;
combining the quantum dot suspension with the cation solution, wherein the cation solution comprises Cd, Zn, Sn, Ag, Au, Hg, Cu, and/or In cations;
heating the combined quantum dot suspension and cation solution to a temperature from 20-150° C.; and
maintaining the temperature for a time of 1-60 minutes.

41. The method of claim 40, wherein the temperature and time are selected to produce partial cation exchange in the outer layer.

42. The method of claim 40, wherein the cation solution comprises Cd or Zn cations.

43. The method of claim 40, wherein the cation solution comprises 0.5 M cadmium oleate, the temperature is 50-125° C., and the time is 10 minutes.

44. The method of claim 35 wherein the C2-C6 primary amine is t-butylamine.

45. The method of claim 35, wherein exposing the porous metal oxide film to the colloidal capped cation-exchanged quantum dots for an effective period of time comprises exposing the porous metal oxide film on the electrically conducting substrate to a suspension comprising the colloidal capped cation-exchanged quantum dots for 12-48 hours.

46. The method of claim 35, wherein the porous metal oxide film comprises mesoporous TiO₂.

47. The method of claim 35, wherein the porous metal oxide film comprises a first layer comprising mesoporous TiO₂ particles having a diameter of 10 to 30 nm, and a second layer comprising TiO₂ particles having a diameter of 100 to 500 nm.

48. The method of claim 35, further comprising putting the photoanode in a solar cell.

49. The method of claim 48, wherein the solar cell further comprises a counter electrode and a hole-extracting and hole-transporting material in contact with both the photoanode and the counter electrode.
